(19) United States
(12) Patent Application Publication
(10) Pub. No.: US 2022/0372643 A1
(43) Pub. Date: Nov. 24, 2022

(54) CATALYST AND METHOD FOR ELECTROREDUCTION OF CARBON DIOXIDE, CARBON MONOXIDE, OR A COMBINATION THEREOF

(71) Applicant: THE GOVERNING COUNCIL OF THE UNIVERSITY OF TORONTO, Toronto (CA)

(72) Inventors: Xue WANG, Toronto (CA); Edward SARGENT, Toronto (CA)

(73) Assignee: THE GOVERNING COUNCIL OF THE UNIVERSITY OF TORONTO, Toronto (CA)

(21) Appl. No.: 17/740,193

(22) Filed: May 9, 2022

(30) Foreign Application Priority Data
May 10, 2021 (CA) 3117648

(51) Int. Cl. C25B 11/089; C25B 11/055; B05D 1/00; C25B 3/26; C25B 3/07

(52) U.S. Cl. CPC C25B 11/089; C25B 11/055; B05D 1/60; C25B 3/26; C25B 3/07; B05D 2506/15

(57) ABSTRACT

There is provided a catalytic system including a fibrous hydrophobic substrate, a first layer having a first layer thickness including copper or copper alloy nanoparticles covering the polymeric substrate, and a second layer having a second layer thickness over the first layer and including amorphous nitrogen-doped carbon, wherein the catalytic system includes confined interlayer spaces defined by regions where the first layer and the second layer are spaced apart from each other. The catalytic system can be used for catalyzing the electrochemical reduction of carbon dioxide, carbon monoxide, or a combination thereof. Thus, there is also provided a method for the electrochemical reduction of carbon dioxide, carbon monoxide, or a combination thereof, using the catalytic system.

The present application claims priority from Canadian patent application No. 3,117,648 filed on May 10, 2021, the disclosure of which is hereby incorporated by reference in its entirety.

### TECHNICAL FIELD

The technical field generally relates to the electroreduction of carbon dioxide, carbon monoxide, or a combination thereof. More particularly, the technical field relates to a catalytic system for the electroreduction of carbon dioxide, carbon monoxide, or a combination thereof, and a method for electrochemically reducing carbon dioxide, carbon monoxide, or a combination thereof involving such catalytic system.

### BACKGROUND

Electroreduction of CO₂ (CO₂RR) to valuable chemicals provides a promising avenue to the storage of renewable electricity (ref. 1). Although a wide range of different products from C₁ to C₃ have been produced (refs. 2-7), only carbon monoxide (CO), formate, and ethylene have been reported with high Faradaic efficiency (FE) at commercially relevant current densities (>100 mA cm⁻²) (refs. 5-7).

Ethanol is of interest since it possesses a high energy density and is used as a high-octane fuel. It has a correspondingly high market price and consistent global demand (ref. 8). Nowadays, the global market size for ethanol is valued at about US$75 billion/year (ref. 9).

In CO₂RR, ethanol and ethylene are the main competing C₂ products. It is believed that they are derived from a shared key intermediate (HOCCH*), and that ethylene is generated after C—O bond-breaking from HOCCH* (refs. 10, 11). Technoeconomic analysis of CO₂RR systems shows that C₂ production can become profitable only once the partial current density exceeds 100 mA cm⁻² (ref. 8). Recently, CO₂RR to ethylene has been reported with a Faradaic efficiency (FE) of up to 70% with a partial current density of 184 mA cm⁻² (ref. 6).

The best ethanol FE reported among the reports documenting even moderate productivity, i.e., having a total current density higher than 10 mA cm⁻², is 41% (Table 1).

TABLE 1
Comparison of ethanol FE for reports with the
total current density higher than 10 mA cm⁻².

| | | | Cathodic | |
|---|---|---|---|---|
| | FEₑₜₕₐₙₒₗ | J_{geometric, ethanol} | EEₑₜₕₐₙₒₗ | |
| Catalysts | (%) | (mA cm⁻²) | (%) | References |
| Boron-doped Cu | 27 ± 1 | 19 ± 1 | 13 | Ref. 4 |
| Cu₂S—Cu | 25 | 100 | 13 | Ref. 13 |
| CuAg | 25 | 75 | 15 | Ref. 12 |
| CuDAT*-wire | 27 | 75 | 16 | Ref. 15 |
| N-GQD** | 16 | 23 | 9 | Ref. 14 |
| Molecule-Cu | 41 | 124 | 23 | Ref. 16 |

*DAT: 3,5-diamino-1,2,4-triazole;
**GQD: graphene quantum dots

Confinement, namely covering an active electrocatalyst to enable molecules and solutions to intercalate, is a strategy to modulate the activity of catalysts (refs. 17-19). Confined sub-nanometer-thick spaces can function as nanoreactors. The strategy has been utilized in the conversion of CO, syngas, and methane and in the electrolysis of water (refs. 18, 20).

### SUMMARY

Various implementations, features and aspects of the technology are described herein, including in the claims.

In some implementations, there is provided a catalytic system including a fibrous hydrophobic substrate, a first layer having a first layer thickness including copper or copper alloy nanoparticles covering the polymeric substrate, and a second layer having a second layer thickness over the first layer and including amorphous nitrogen-doped carbon, wherein the catalytic system includes confined interlayer spaces defined by regions where the first layer and the second layer are spaced apart from each other.

In some implementations, the fibrous hydrophobic substrate includes hydrophobic nanofibers.

In some implementations, the fibrous hydrophobic substrate includes polymeric nanofibers, carbon nanofibers, or a combination thereof.

In some implementations, the fibrous hydrophobic substrate includes at least one fluoropolymer.

In some implementations, the fibrous hydrophobic substrate includes polytetrafluoroethylene (PTFE).

In some implementations, the fibrous hydrophobic substrate includes a nanofibers membrane.

In some implementations, the fibrous hydrophobic substrate includes a nanofibers membrane having a pore size ranging from about 200 nm to about 700 nm.

In some implementations, the fibrous hydrophobic substrate includes a nanofibers membrane having an average pore size from about 400 nm to about 500 nm.

In some implementations, the fibrous hydrophobic substrate includes nanofibers having a diameter ranging from about 50 nm to about 200 nm.

In some implementations, the first layer thickness is from about 100 nm to about 500 nm.

In some implementations, the first layer thickness is from about 100 nm to about 300 nm.

In some implementations, the first layer thickness is from about 150 nm to about 250 nm.

In some implementations, the copper or copper alloy nanoparticles have a diameter ranging from about 20 nm to about 100 nm.

In some implementations, the first layer includes copper nanoparticles.

In some implementations, in the second layer, the amorphous nitrogen-doped carbon includes electron-donating nitrogen atoms.

In some implementations, an atomic percentage of nitrogen in the second layer is from about 3% to about 50%.

In some implementations, an atomic percentage of nitrogen in the second layer is from about 10% to about 50%.

In some implementations, an atomic percentage of nitrogen in the second layer is from about 25% to about 40%.

In some implementations, the second layer includes pyridinic-N, pyrrolic-N and graphitic-N.

In some implementations, a content of pyridinic-N is higher than a content of pyrrolic-N or graphitic-N.

In some implementations, the second layer includes pyridinic-N in an atomic percentage from about 10% to about 21%.

In some implementations, the second layer thickness is from about 20 nm to about 100 nm.

In some implementations, the second layer thickness is from about 30 nm to about 70 nm.

In some implementations, the second layer thickness is from about 40 nm to about 60 nm.

In some implementations, the second layer includes a plurality of pores extending through the second layer thickness.

In some implementations, the pores in the second layer have an average diameter from about 5 nm to about 20 nm.

In some implementations, the pores in the second layer have an average diameter from about 5 nm to about 15 nm.

In some implementations, the first layer and the second layer are spaced apart from each other in the confined interlayer spaces by a distance that is about 1 nm or below.

In some implementations, the first layer and the second layer are spaced apart from each other in the confined interlayer spaces by a distance that is from about 0.6 nm to about 1 nm.

In some implementations, the first layer and the second layer are spaced apart from each other in the confined interlayer spaces by a distance that is from about 0.6 nm to about 0.9 nm.

In some implementations, there is also provided a membrane electrode assembly system including a cathode side and an anode side, wherein the cathode side includes the catalytic system as defined herein.

In some implementations, the anode side of the membrane electrode assembly system includes an anode catalyst.

In some implementations, the anode catalyst includes an iridium oxide supported on titanium mesh.

In some implementations, the membrane electrode assembly system further includes an anion exchange membrane between the cathode side and the anode side.

In some implementations, there is also provided a use of the membrane electrode assembly system as defined herein, for the electroreduction of carbon dioxide, carbon monoxide, or a combination thereof. In some implementations, the electroreduction reaction can produce at least one of ethanol, n-propanol, ethylene, acetate and/or acetic acid, formate and/or formic acid, methane, and hydrogen. In some implementations, CO can be produced from the electroreduction of carbon dioxide using the membrane electrode assembly system as defined herein. In further implementations, the membrane electrode assembly system as defined herein can particularly be used for the electroreduction of carbon dioxide, carbon monoxide, or a combination thereof, into ethanol.

In some implementations, there is also provided a method for electrochemical reduction of carbon dioxide, carbon monoxide, or a combination thereof, including:
contacting a reactant gas including carbon dioxide, carbon monoxide, or a combination thereof, in the presence of an electrolyte, with a cathode including the catalytic system as defined herein;
applying a voltage to provide a current density to cause the carbon dioxide, carbon monoxide, or the combination thereof, in the reactant gas contacting the cathode, to be electrochemically reduced.

In some implementations, there is also provided a method for electrochemical production of ethanol from carbon dioxide, carbon monoxide, or a combination thereof, including:
contacting a reactant gas including carbon dioxide, carbon monoxide, or a combination thereof, in the presence of an electrolyte, with a cathode including the catalytic system as defined herein;
applying a voltage to provide a current density to cause the carbon dioxide, carbon monoxide, or the combination thereof in the reactant gas contacting the cathode, to be electrochemically converted into ethanol.

In some implementations, the reactant gas including carbon dioxide, carbon monoxide, or a combination thereof is humidified before contacting with the cathode.

In some implementations, the reactant gas includes carbon dioxide.

In some implementations, the reactant gas includes a pure CO₂ gas, an enriched CO₂-containing gas or a diluted CO₂-containing gas.

In some implementations, the reactant gas includes a pure CO₂ gas, a flue gas, or biogenic CO₂.

In some implementations, the reactant gas includes carbon monoxide.

In some implementations, the reactant gas includes both carbon dioxide and carbon monoxide.

In some implementations, the electrolyte includes a KOH or KHCO₃ aqueous solution.

In some implementations, there is also provided a process for producing a catalytic system as defined herein, including:
sputtering copper or the copper alloy onto the fibrous hydrophobic substrate to form the first layer; and
sputtering the nitrogen-doped carbon onto the first layer to form the second layer.

In some implementations, sputtering includes magnetron sputtering deposition.

In some implementations, the first layer is formed from a copper or copper alloy target, in an argon environment, at a sputtering rate from about 0.5 Å s⁻¹ to about 1.5 Å s⁻¹.

In some implementations, the second layer is formed from a graphite target, in a N₂ and argon environment, at a sputtering rate from about 0.01 Å s⁻¹ to about 0.1 Å s⁻¹.

In some implementations, graphite sputtering is performed at a flow rate ratio of N₂ to argon from about 2/20 sccm to about 20/20 sccm.

In some implementations, the first layer is formed from a copper target, in an argon environment, at a sputtering rate of about 1.1 Å s⁻¹; and the second layer is formed from a graphite target, in a N₂ and argon environment, at a sputtering rate of about 0.05 Å s⁻¹ and a flow rate ratio of N₂ to argon from about 2/20 sccm to about 20/20 sccm.

### DESCRIPTION OF DRAWINGS

FIG. 1: DFT calculations. Cu, N, C and O atoms are illustrated as orange, blue, grey and red balls, respectively, while water molecules are shown as lines. a, Geometries of dimerized OCCO* intermediate on N—C/Cu and C/Cu. b, Energy profiles for initial states (ISs), transition states (TSs), and final states (FSs) of CO dimerization on Cu, C/Cu and N—C/Cu, respectively. c,d, Electron density difference plots for N—C/Cu (c) and C/Cu (d) with two adsorbed *CO and one charged water layer, respectively. Yellow contours represent charge accumulations, and blue contours denote charge depressions. e, Reaction energies of the ethylene pathway (HOCCH* to CCH*) and the ethanol pathway (HOCCH* to HOCHCH*) on Cu, N—C/Cu and amorphous N—C/Cu. f, Illustration of CO₂ intercalation at the N—C/Cu interface and the production of ethanol.

FIG. 2: Structural and compositional analyses of the 34% N—C/Cu catalyst on PTFE. a, Low-magnification scanning electron microscopy (SEM) image of the 34% N—C/Cu catalyst on PTFE. b, EDX elemental mapping of Cu, N and C for the 34% N—C/Cu catalyst on PTFE. c, Scheme of the cross-sectional structure of a N—C/Cu/PTFE nanofibre. The white, orange and green layers represent PTFE, Cu and N—C, respectively. d,e, Secondary electron image (d) and the corresponding high-angle annular dark-field scanning transmission electron microscopy (HAADF-STEM) image, as well as the elemental mapping of Cu, N and C taken from a section of one 34% N—C/Cu/PTFE nanofibre (e). f,g, High-resolution C1 s (f) and N1 s spectra (g) for 34% N—C/Cu catalyst on PTFE. (a.u., arbitrary units.) h, HAADF-STEM image of the 34% N—C/Cu ultrathin section. i, Higher-magnification HAADF-STEM image (top) taken from the area marked by the box in h and its intensity profile (the unit of intensity is a.u.) taken along the rectangular frame (bottom), displaying the distance between the Cu layer and the N—C layer, d_{N—C/Cu}.

FIG. 3: CO₂RR performance comparisons. a, FE values of C₂₊ products on Cu (the hatched bars) and 34% N—C/Cu catalysts under different current densities. Error bars represent the standard deviation of measurements based on three independent samples. b, Partial ethanol current densities jₑₜₕₐₙₒₗ versus potentials referred to the reversible hydrogen electrode (RHE) on 34% N—C/Cu and Cu catalysts. Error bars denote the standard deviation of potentials (n>300) during the constant-current electrolysis. c, Ethanol FE values on different catalysts under different current densities. Error bars represent the standard deviation of measurements based on three independent samples. d, Comparison of ethanol FE values for different catalysts at 300 mA cm⁻². Error bars represent the standard deviation of measurements based on three independent samples. e, Comparison of the ratios of FEₑₜₕₐₙₒₗ to FE_{ethylene} on different catalysts under different current densities.

FIG. 4: In situ Raman and XAS characterization. a, In situ Raman spectra of the 34% N—C/Cu catalyst during CO₂RR under different applied potentials. The regions of 240-450 cm⁻¹ and 1,900-2,150 cm⁻¹ are shaded. b, Comparison of in situ Raman spectra of 34% N—C/Cu and Cu catalysts in the range of 253-430 cm⁻¹. The region of 325-430 cm⁻¹ showing Cu—CO stretch (vCu—CO) is shaded. All given potentials are referred to the reversible hydrogen electrode (RHE). c, In operando Cu K-edge XANES spectra of different catalysts during CO₂RR by applying 300 mA cm⁻² for 16 s. Bulk Cu foil, CuO and Cu₂O are listed as references. d, Surface-sensitive total-electron-yield XANES spectra at the nitrogen K-edge on different N—C/Cu catalysts.

FIG. 5: Geometries of carbon and nitrogen-doped carbon layers. a,b, Top views of carbon layer (a) and nitrogen-doped carbon layer (b). Blue and grey balls stand for nitrogen and carbon atoms, respectively. These notations are used throughout this document.

FIG. 6: Geometries of CO dimerization initial state. a-c, Top views of CO dimerization initial state on Cu (a), Cu with carbon layer (b), and Cu with nitrogen-doped carbon layer (c). d-f, The corresponding side views of CO dimerization initial state on Cu (d), Cu with carbon layer (e), and Cu with nitrogen-doped carbon layer (f). Red, grey, white, orange balls are oxygen, carbon, hydrogen, and copper, respectively. Water molecules are shown as red lines. These notations are used throughout this document. All the Cu models in DFT throughout this work are Cu(111) surface if not specified.

FIG. 7: Geometries of CO dimerization transition state. a-c, Top views of CO dimerization transition state on Cu (a), Cu with carbon layer (b), and Cu with nitrogen-doped carbon layer (c). d-f, The corresponding side views of CO dimerization initial state on Cu (d), Cu with carbon layer (e), and Cu with nitrogen-doped carbon layer (f).

FIG. 8: Geometries of CO dimerization final state. a-c, Top views of CO dimerization transition state on Cu (a), Cu with carbon layer (b), and Cu with nitrogen-doped carbon layer (c). d-f, The corresponding side views of CO dimerization initial state on Cu (d), Cu with carbon layer (e), and Cu with nitrogen-doped carbon layer (f).

FIG. 9: Scheme of ethanol and ethylene pathways.

FIG. 10: Geometries of key intermediate HOCCH*. a-c, Top views of key intermediate (HOCCH*) branching ethylene and ethanol pathways on Cu (a), Cu with carbon layer (b), and Cu with nitrogen-doped carbon layer (c). d-f, The corresponding side views of key intermediate (HOCCH*) branching ethylene and ethanol pathway on Cu (d), Cu with carbon layer (e), and Cu with nitrogen-doped carbon layer (f).

FIG. 11: Geometries of intermediate HOCCH* on Cu(111) with different layers of graphite: one layer (a), two layers (b), and three layers (c).

FIG. 12: Geometries of the intermediate CCH*. a-c, Top views of the intermediate (CCH*) in ethylene pathway on Cu (a), Cu with carbon layer (b), and Cu with nitrogen-doped carbon layer (c). d-f, The corresponding side views of the intermediate (CCH*) in ethylene pathway on Cu (d), Cu with carbon layer (e), and Cu with nitrogen-doped carbon layer (f).

FIG. 13: Geometries of the intermediate HOCHCH*. a-c, Top views of the intermediate (HOCHCH*) in ethanol pathway on Cu (a), Cu with carbon layer (b), and Cu with nitrogen-doped carbon layer (c). d-f, The corresponding side views of the intermediate (HOCHCH*) in ethanol pathway on Cu (d), Cu with carbon layer (e), and Cu with nitrogen-doped carbon layer (f).

FIG. 14: Geometries of key intermediate HOCCH* with different distances between N—C layer and Cu layer (d_{N—C/Cu}) with two adsorbed *CO and one charged water layer. a, d_{N—C/Cu}=6.42 Å. b, d_{N—C/Cu}=8.42 Å. c, d_{N—C/Cu}=9.42 Å.

FIG. 15: Geometries of the intermediate CCH* with difference d_{N—C/Cu} with two adsorbed *CO and one charged water layer. a, d_{N—C/Cu}=6.42 Å. b, d_{N—C/Cu}=8.42 Å. c, d_{N—C/Cu}=9.42 Å.

FIG. 16: Geometries of the intermediate HOCHCH* with difference d_{N—C/Cu} with two adsorbed *CO and one charged water layer. a, d_{N—C/Cu}=6.42 Å. b, d_{N—C/Cu}=8.42 Å. c, d_{N—C/Cu}=9.42 Å.

FIG. 17: Pipeline for the generation of amorphous N-doped carbon structures.

FIG. 18: Distribution of formation energy per atom for amorphous carbon on the Cu surface. Intermediates and water are taken into account. The distribution of all vs. unreconstructed amorphous structures are shown in red and orange, respectively.

FIG. 19: Distribution of formation energy per atom for amorphous N-doped carbon on the Cu. Intermediates and water are taken into account. The distribution of all vs. unreconstructed amorphous structures are shown in red and orange, respectively.

FIG. 20: SEM image of sputtered Cu on PTFE.

FIG. 21: HAADF-STEM images of Cu-PTFE (a) and 34% N—C/Cu-PTFE (b).

FIG. 22: Structural analysis of Cu-PTFE and 34% N—C/Cu-PTFE. a-c, HAADF-STEM image of Cu-PTFE (a) and higher magnification bright field STEM (b) and the corresponding HAADF-STEM image (c) taken from the area marked by the box in (a). d-f, HAADF-STEM image of 34% N—C/Cu-PTFE (d) and higher magnification bright field STEM (e) and the corresponding HAADF-STEM image (f) taken from the area marked by the box in (d). There is no observable morphology difference on Cu between Cu-PTFE and 34% N—C/Cu-PTFE.

FIG. 23: Cross-section characterization for the electrode of 34% N—C/Cu on PTFE. a-g, Cross-section SEM image (a), the corresponding EDX elemental mapping of Cu, N, C, and F (b-f), and the corresponding EDX analysis (g) for 34% N—C/Cu on PTFE. The EDX elemental mapping and EDX analysis of F is used to distinguish PTFE substrate.

FIG. 24: SEM image (a), and secondary electron image (b) and the corresponding HAADF-STEM image (c) of 34% N—C/Cu catalyst on PTFE. The holes on the N—C layer are indicated using dotted lines.

FIG. 25: Structural and compositional analyses of the prepared ultrathin slice of 34% N—C/Cu. a, HAADF-STEM image of the 34% N—C/Cu ultrathin slice. b, Higher magnification HAADF-STEM image taken from the area marked by a box in (a). c, HAADF-STEM image of the area marked in (a) and the corresponding EELS elemental mappings of Cu, N, and F.

FIG. 26: XRD patterns for PTFE substrate and different electrodes. The peaks marked by gray and red dot lines come from PTFE substrate and Cu, respectively.

FIG. 27: Structural characterization of different electrodes and PTFE substrate. a-e, WAXS maps for 26% N—C/Cu (a), 34% N—C/Cu (b), 39% N—C/Cu (c), C/Cu (d), and sputtered Cu (e) on PTFE substrates. f, WAXS map for PTFE substrate.

FIG. 28: Sector-averages of WAXS maps in FIG. 27 for different electrodes and PTFE substrate. The peaks marked by gray and red dot lines come from PTFE substrates and Cu, respectively.

FIG. 29: Structural analysis of ultrathin slice of 34% N—C/Cu. a, HAADF-STEM image of the 34% N—C/Cu ultrathin section. b, Higher magnification HAADF-STEM image taken from the area marked by the box in (a) and its intensity profile taken along the rectangular frame displaying the distances between Cu layer and N—C layer.

FIG. 30: CVs for different samples in 1 M KOH by supplying different gases to gas chamber of the cell. a, N₂. b, CO₂.

FIG. 31: The resistance between the working and reference electrodes determined by EIS technique and the corresponding iR drop in the course of the electrolysis at 300 mA cm⁻².

FIG. 32: CO₂RR performance of 34% N—C GDE under different current densities. Error bars represent the standard deviation of measurements based on three independent samples.

FIG. 33: CVs for different samples measured in 100 mM HClO₄+1 mM Pd(ClO₄)₂.

FIG. 34: Partial ethanol current density normalized to Cu_{ECSA} for Cu and 34% N—C/Cu catalysts versus potential for CO₂RR. Error bars denote the standard deviation of potentials (n>300) during the constant-current electrolysis.

FIG. 35: NMR spectra of liquid products. a, Representative ¹H-NMR spectrum of catholyte after CO₂RR on 34% N—C/Cu cathodes by applying 300 mA cm⁻² in 1 M KOH. DMSO is used as an internal standard. b-e, The corresponding enlarged ¹H-NMR spectra demonstrating ethanol and n-propanol (b), acetate (c), ethanol (d), and formate (e).

FIG. 36: NMR spectra of liquid products obtained from ¹³C-labelling experiment. a, ¹H-NMR spectrum of catholyte after ¹³CO₂RR on 34% N—C/Cu cathodes by applying 300 mA cm⁻² in 1 M KOH. b,c, The corresponding enlarged ¹H-NMR spectra demonstrating that ethanol is produced from ¹³CO₂RR.

FIG. 37: SEM images of catalysts: 26% N—C/Cu (a), 39% N—C/Cu (b), and C/Cu (c).

FIG. 38: SEM images of catalysts: 26% N—C/Cu (a,b), 39% N—C/Cu (c,d), and C/Cu (e,f). The holes on N—C and C layers are marked using dotted lines.

FIG. 39: Structural and compositional analyses of the N—C/Cu catalysts on PTFE. a-e, SEM image (a) and the corresponding EDX elemental mapping (b-e) of Cu, N, and C for 26% N—C/Cu. f-j, SEM image (f) and the corresponding EDX elemental mapping (g-j) of Cu, N, and C for 39% N—C/Cu.

FIG. 40: XPS analysis for different N—C/Cu catalysts on PTFE. a,b, High-resolution C1s (a) and N1s (b) spectra for 26% N—C/Cu catalyst on PTFE. c,d, High-resolution C1s (c) and N1s (d) spectra for 39% N—C/Cu catalyst on PTFE.

FIG. 41: Schematic of CO₂RR configuration for N—C on Cu catalyst layer.

FIG. 42: In situ Raman spectra of 34% N—C/Cu in Ar-saturated KOH under different applied potentials.

FIG. 43: In situ Raman spectra of Cu catalyst during CO₂RR under different applied potentials.

FIG. 44: Operando Cu K-edge extended X-ray adsorption fine structure (EXAFS) spectra of different catalysts during CO₂RR by applying 300 mA cm⁻². Bulk Cu foil, CuO, and Cu₂O are listed as references.

FIG. 45: Operando XAS characterizations. a,b, Operando Cu K-edge XANES (a) and EXAFS spectra (b) of 34% N—C/Cu catalyst during CO₂RR by applying 300 mA cm⁻². Bulk Cu foil, CuO, and Cu₂O are listed as references.

FIG. 46: Potassium K-edge EXAFS spectra of KOH dissolved in DI water and absorbed K+ on 34% N—C/Cu after CO₂RR with KOH as the electrolyte. After CO₂RR, the catalyst was rinsed using DI water to remove the KOH solution on the surface of catalyst and was dried by N₂ before ex-situ XAS measurement. The peaks 1, 2, and 3 can be assigned as adsorbed K⁺ on C, K⁺—OH⁻, and adsorbed K⁺ on Cu, respectively (refs. 73-76).

FIG. 47: Comparison of ethanol FEs on different types of N—C/Cu catalysts under different current densities: a, 100 mA cm⁻²; b, 200 mA cm⁻². Error bars represent the standard deviation of measurements based on three independent samples.

FIG. 48: Nitrogen K-edge XANES spectra of different N—C/Cu catalysts recorded in PFY mode.

FIG. 49: Schematic diagram of the MEA system. The total geometric area of the flow field in the cathode is 5 cm², where 45% is the gas channel area and 55% is the land area.

FIG. 50: CO₂RR performance in MEA system. a,b, FEs of different products and current densities in CO₂RR on 34% N—C/Cu catalyst (a) and Cu catalyst (b) under different cell voltages. The color scheme in (b) also applies to panel (a). Error bars represent the standard deviation of measurements based on three independent samples.

FIG. 51: CO₂RR performance comparisons in MEA system. a, FEs of C₂₊ products on 34% N—C/Cu and Cu (the hatched bars) catalysts under different cell voltages. Error bars represent the standard deviation of measurements based on three independent samples. b, Comparison of the ratios of FEₑₜₕₐₙₒₗ to FE_{ethylene} on 34% N—C/Cu and Cu catalysts under different cell voltages.

FIG. 52: Performance test of CO₂RR to ethanol in MEA system during 15 hours of electrolysis under the full-cell voltage of −3.67 V.

FIG. 53: XRD patterns for 34% N—C/Cu catalyst on PTFE after 15 h electrolysis and bare PTFE substrate. The peaks marked by gray and red dot lines come from PTFE substrate and Cu, respectively.

FIG. 54: Structural and compositional analyses of the 34% N—C/Cu catalyst on PTFE after 15 h electrolysis. a,b, Low magnification SEM image (a) and EDX elemental mapping of Cu, N, and C (b) for 34% N—C/Cu catalyst on PTFE after 15 h electrolysis.

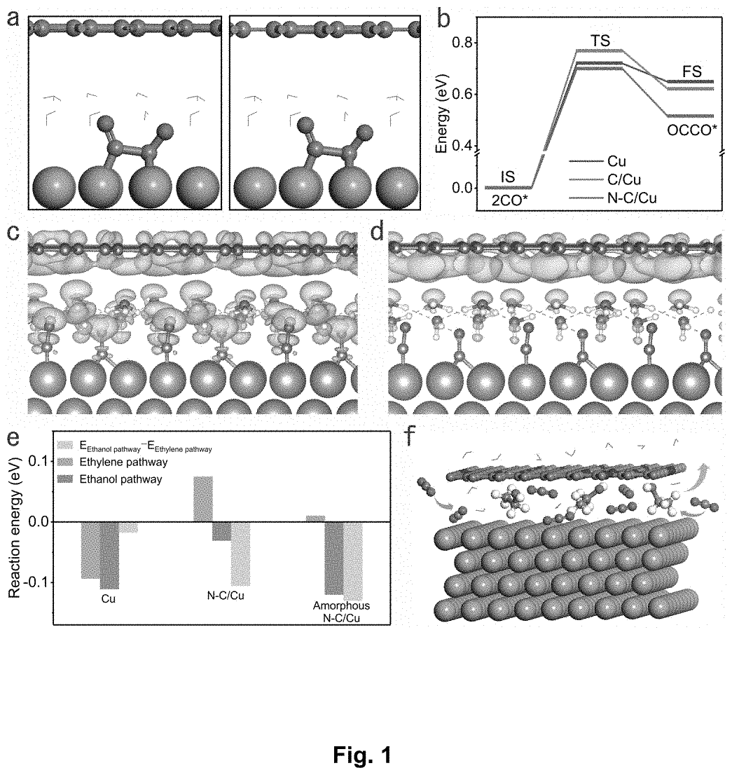

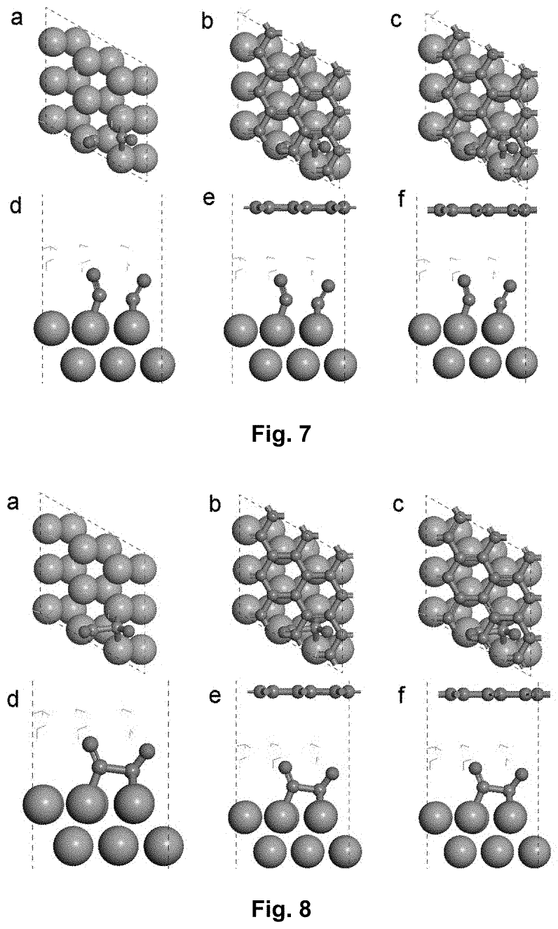

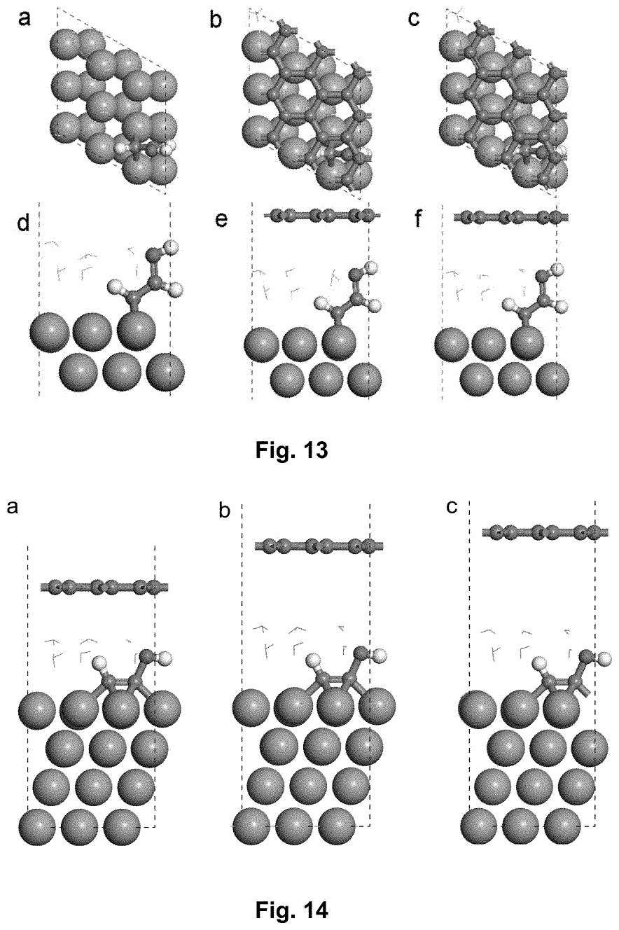

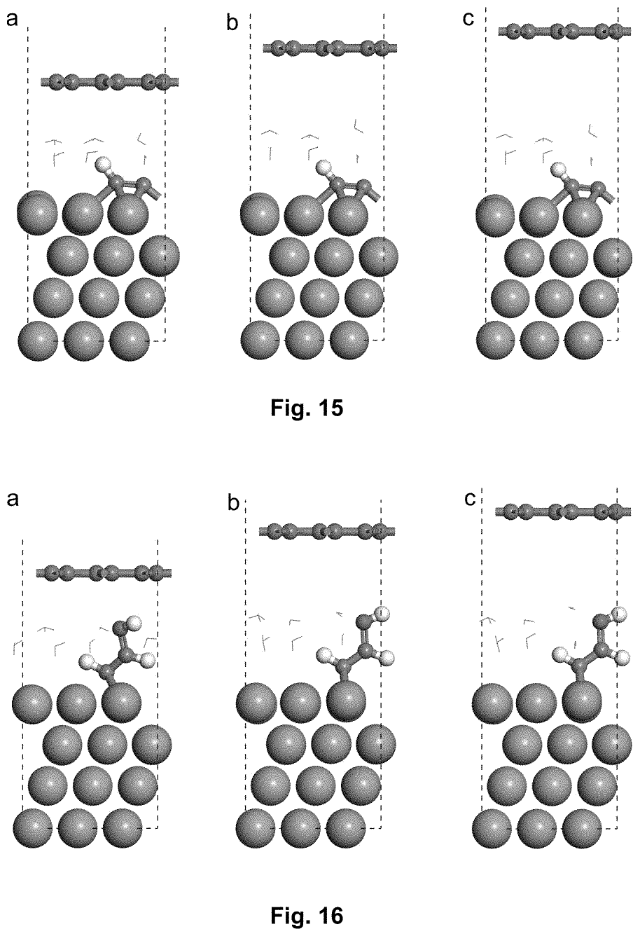

In FIGS. 1 and 6 to 15, concerning DFT calculations/geometries, reference to “N—C” or “nitrogen-doped carbon”, without mentioning “amorphous” before, means “crystalline” N—C or nitrogen-doped carbon. In all the other figures, if not already specified, reference to “N—C” or “nitrogen-doped carbon” means “amorphous” N—C or nitrogen-doped carbon.

### DETAILED DESCRIPTION

The present description relates to a catalytic system for the electroreduction of carbon dioxide, carbon monoxide, or a combination thereof. The present description also relates to a method for electrochemically reducing carbon dioxide, carbon monoxide, or a combination thereof involving such catalytic system.

In some implementations, the catalytic system includes a fibrous hydrophobic substrate, a first layer having a first layer thickness including copper or copper alloy nanoparticles covering the polymeric substrate, and a second layer having a second layer thickness over the first layer and including amorphous nitrogen-doped carbon. The catalytic system further includes confined interlayer spaces defined by regions where the first layer and the second layer are space apart from each other.

As used herein the expression “fibrous hydrophobic substrate” refers to a substrate made of fibres onto which the copper-based catalyst can be applied. The fibrous substrate is hydrophobic meaning that the fibres, at least on their surface, can repel water. Hence, the fibres can include a hydrophobic coating to provide the hydrophobic properties to the fibrous substrate. In some implementations, the whole fibres can be made of a hydrophobic material.

Various material possessing hydrophobic properties can be employed and are known in the field. In some implementations, the fibrous hydrophobic material can include a hydrophobic organic polymer. In other implementations, the fibrous hydrophobic material can include carbon fibers. In some implementations, the fibrous hydrophobic material can include a combination of a hydrophobic organic polymer and carbon fibers, or any other hydrophobic material.

In some implementations, the fibrous hydrophobic substrate of the catalytic system can include one or more fluoropolymers as the hydrophobic material making of the fibers. An example of such fluoropolymer is polytetrafluoroethylene (PTFE).

In some implementations, the fibers of the hydrophobic substrate are in the nanometric size range. In other words, the hydrophobic substrate to which the copper-based layer and then the nitrogen-doped carbon layer are deposited, can include nanofibers made of a hydrophobic material. In some implementations, the fibrous hydrophobic substrate can thus include nanofibers made of the above-described hydrophobic materials, such as, fluoropolymer nanofibers (e.g., PTFE nanofibers), carbon nanofibers, or a combination thereof. In some implementations, the nanofibers can have a diameter ranging from about 50 nm to about 200 nm. Hence, in some implementations, the nanofibers can have a diameter of about 50 nm, 60 nm, 70 nm, 80 nm, 90 nm, 100 nm, 110 nm, 120 nm, 130 nm, 140 nm, 150 nm, 160 nm, 170 nm, 180 nm, 190 nm, 200 nm, or any value between these values. In some implementations, the nanofibers can have an average diameter of about 100 nm. In some implementations, there is no limitation to the length of the nanofibers. The term “about” as used herein, indicates that a value includes the standard deviation of error for the device or method being employed in order to determine the value. In general, the terminology “about” is meant to designate a possible variation of up to 10%. Therefore, a variation of 1, 2, 3, 4, 5, 6, 7, 8, 9 and 10% of a value is included in the term “about”. Unless indicated otherwise, use of the term “about” before a range applies to both ends of the range.

In some implementations, the fibrous hydrophobic substrate can be in the form of a membrane including the nanofibers described above. In other words, the substrate can include a plurality of nanofibers assembled to form a matrix presenting a porous structure. The presence of pores in the membrane can allow gas and/or electrolyte diffusion when the catalytic system is integrated into a membrane electrode assembly as will be described below. In some implementations, the nanofibers membrane that can be used as the hydrophobic substrate, can present a porous structure with a pore size ranging from about 200 nm to about 700 nm. Hence, in some implementations, the size of the pores in the porous hydrophobic nanofibers membrane can be about 200 nm, 250 nm, 300 nm, 350 nm, 400 nm, 450 nm, 500 nm, 550 nm, 600 nm, 650 nm, 700 nm, or any value between these values. In some implementations, the pores of the nanofibers membrane can have an average pore size ranging from about 400 nm to about 500 nm. In some implementations, a nanofibers membrane having an average pore size of about 450 nm can be used as the substrate for the catalytic system.

As previously mentioned, the fibrous hydrophobic substrate (e.g., the nanofibers and/or nanofibers membrane described herein) is covered with a first conductive layer and then with a second layer over the first layer. By “covered”, one means that at least a portion of the fibrous hydrophobic substrate is coated with the first layer and the second layer. In some implementations, the whole surface of the fibrous hydrophobic substrate can be substantially coated with the first layer and then the second layer. In some implementations, minimal portions of the fibrous hydrophobic substrate remain uncoated.

The first layer covering the fibrous hydrophobic substrate can include a conductive metal such as copper. In some implementations, the first layer can include nanoparticles of a copper-based material, such as copper nanoparticles or copper alloy nanoparticles. When the first layer includes copper alloy nanoparticles, the alloy can include CuZn, CuAg, CuAu, to name a few examples. In some implementations, the metallic nanoparticles forming the first layer can have a diameter ranging from about 20 nm to about 100 nm. Hence, in some implementations, the diameter of the first layer nanoparticles can be about 20 nm, 30 nm, 40 nm, 50 nm, 60 nm, 70 nm, 80 nm, 90 nm, 100 nm, or any value between these values. Even if the present description generally discusses a first layer including copper-based nanoparticles, it is worth noting that in some implementations, the first layer could include alternative conductive nanoparticles, as soon as the first layer and the nitrogen-doped carbon second layer disposed on the substrate can form confined interlayer spaces or regions, as will be explained in further detail below.

In some implementations, the first layer of the catalytic system, namely the layer coated over the fibrous hydrophobic substrate can be characterized by a thickness ranging from about 100 nm to about 500 nm. In some implementations, the thickness of the first layer can range from about 100 nm to about 400 nm, or from about 100 nm to about 300 nm, or from about 100 nm to about 250 nm, or from about 150 nm to about 250 nm. In some implementations, the thickness of the first layer can be about 100 nm, 150 nm, 200 nm, 250 nm, 300 nm, 350 nm, 400 nm, 450 nm, 500 nm, or any value between these values. Although the thickness of the first layer can vary, an average thickness having a value mentioned herein can provide a suitable catalytic system. One will also understand that the thickness of the first layer can slightly vary in different regions of the substrate's surface, with regions having slightly higher or smaller thickness than other regions.

The second layer that is present over the first layer on the fibrous hydrophobic substrate (e.g., the nanofibers and/or nanofibers membrane described herein) includes nitrogen-doped carbon and more particularly amorphous nitrogen-doped carbon. In some implementations, the second layer includes amorphous nitrogen-doped carbon including electron-donating nitrogen atoms. By “nitrogen-doped”, it is meant that nitrogen atoms are introduced in the solid structure of the basis carbon material. For instance, some carbon atoms can be replaced with nitrogen atoms in the material structure. In some implementations, the atomic percentage of nitrogen in the second layer can be from about 3% to about 50%. For instance, the atomic percentage of nitrogen in the second layer can be from about 10% to about 50%, or from about 10% to about 50%, or from about 20% to about 50%, or from about 20% to about 45%, or from about 25% to about 45%, or from about 25% to about 40%. In some implementations, the atomic percentage of nitrogen in the second layer can be from about 26% to about 39%. In some implementations, the atomic percentage of nitrogen in the second layer can be 25%, 26%, 27%, 28%, 29%, 30%, 31%, 32%, 33%, 34%, 35%, 36%, 37%, 38%, or 39%. In some implementations, the nitrogen atoms in the nitrogen-doped carbon material can be included in pyridinic, pyrrolic and/or graphitic structures. In other words, the second layer can include pyridinic-N, pyrrolic-N, graphitic-N, or any combination thereof. In some implementations, one can find nitrogen atoms being pyridinic-N, pyrrolic-N and graphitic-N in the second layer. In certain implementations, the content of pyridinic-N, in the second layer, is higher than the content of pyrrolic-N or graphitic-N. In further implementations, the second layer can include pyridinic-N in an atomic percentage from about 10% to about 21%. Hence, in some implementations, the pyridinic-N can be present in an atomic percentage of about 10%, 11%, 12%, 13%, 14%, 15%, 16%, 17%, 18%, 19%, 20%, or 21%, in the second layer. The presence of pyridinic-N can enhance the electron-donating ability of the nitrogen-doped carbon layer due to the presence of the lone electron pair of the nitrogen atom in the plane of the carbon matrix. This can further allow increasing at least ethanol Faradaic efficiency (FE) during electroreduction of carbon dioxide and/or carbon monoxide, particularly carbon dioxide, using the present catalytic system.

As mentioned above, the nitrogen-doped carbon material in the second layer includes amorphous nitrogen-doped carbon. By “amorphous”, it is meant that the nitrogen-doped carbon mainly includes non-crystalline nitrogen-doped carbon. The second layer thus mostly includes nitrogen-doped carbon presenting an amorphous structure, but the presence of crystalline structure is not excluded. In some implementations, the second layer can only include amorphous nitrogen-doped carbon. The second layer including nitrogen-doped carbon being amorphous, can be beneficial to the catalytic system. For instance, it was observed that CO₂ reduction using a catalytic system as described herein, including nitrogen-doped carbon with an amorphous structure can improve ethanol selectivity vs. ethylene.

In some implementations, the second layer of the catalytic system can have a thickness that can be lower than the thickness of the first layer of copper-based nanoparticles onto which it is applied, although both layers could have substantially the same thickness. In some implementations, the second layer thickness can range from about 20 nm to about 100 nm. Hence, in some implementations, the thickness of the second layer can range from about 20 nm to about 90 nm, or from about 20 nm to about 80 nm, or from about 20 nm to about 70 nm, or from about 30 nm to about 70 nm, or from about 40 nm to about 60 nm. In some implementations, the thickness of the second layer can be about 40 nm, 50 nm, 60 nm, 70 nm, 80 nm, 90 nm, 100 nm, or any value between these values. Although the thickness of the second layer can be varied, an average thickness having a value mentioned herein can provide a suitable catalytic system. One will also understand that the thickness of the second layer can slightly vary in different regions over the substrate, with regions having slightly higher or smaller thickness than other regions.

In some implementations, the second layer in the catalytic system can further include a plurality of pores extending through a thickness thereof. In other words, pores can be present in the second layer, which can extend from the surface of the second layer that is opposite to the surface disposed over the first layer, towards the first layer. These pores present in the second layer can have an average diameter ranging from about 5 nm to about 20 nm. In some implementations, the pores in the second layer can have an average diameter ranging from about 5 nm to about 15 nm. Hence, in some implementations, the average size of the pores in the second layer can be about 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, or 20 nm.

Another characteristic of the catalytic system described herein, is the presence of confined interlayer spaces between the first layer and the second layer. More particularly, the catalytic system includes regions where the first layer and the second layer are spaced apart from each other separated by regions where both layers are adjoined. The regions where the layers are spaced apart define the so-called confined interlayer spaces. In other words, the structure of the catalytic system is such that the second layer is at a certain distance from the first layer in certain regions of the bilayer assembly. The presence of confined regions can enable molecules and solutions to intercalate between the two layers, which, in turn, can allow to enhance the activity of the catalytic system. More specifically, in the case of CO₂ and/or CO electroreduction, the CO₂ and/or CO molecules, reaction intermediates (which can include CO molecules when the reactant gas includes CO₂) and products can be confined within the interlayer spaces. Hence, the reaction can occur within the confined interlayer spaces and such spaces can thus function as nanoreactors. In some implementations, in the present catalytic system, the first layer and the second layer can be spaced apart from each other, in the confined interlayer spaces, by a distance that is about 1 nm or below. In some implementations, the distance between the first layer and the second layer in the confined interlayer spaces can be from about 0.6 nm to about 1 nm, or from about 0.6 nm to about 0.9 nm. Hence, in some implementations, the distance between the first layer and the second layer in the confined interlayer spaces can be about 0.6 nm, 0.7 nm, 0.8 nm, 0.9 nm, or 1 nm.

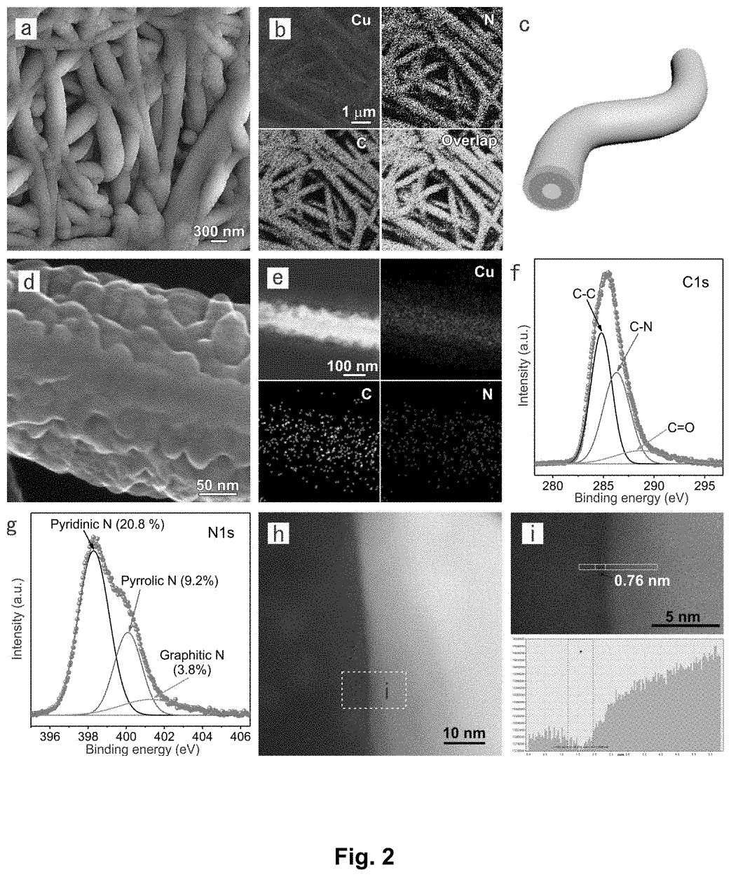

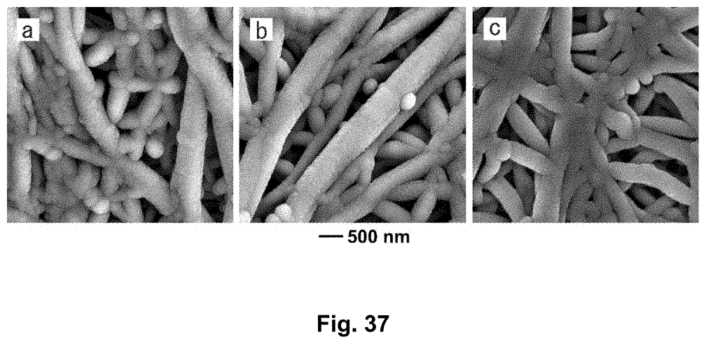

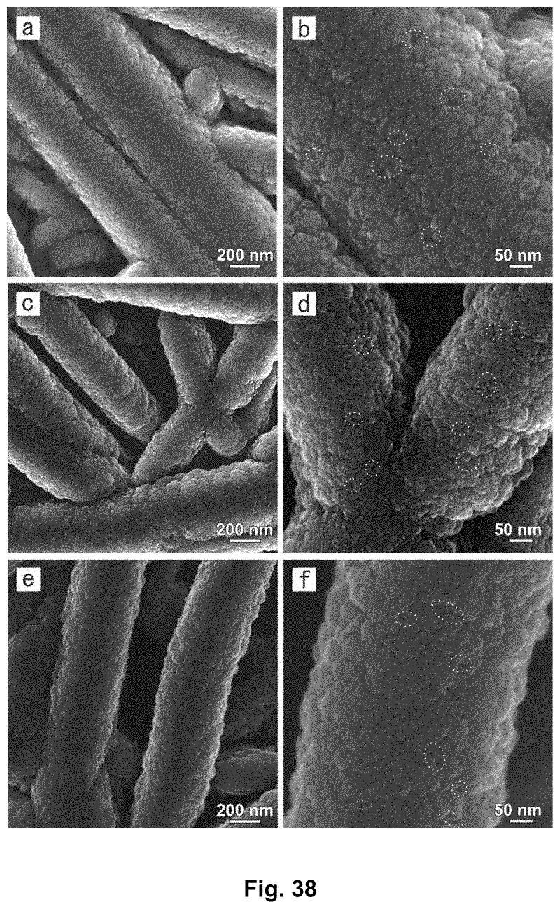

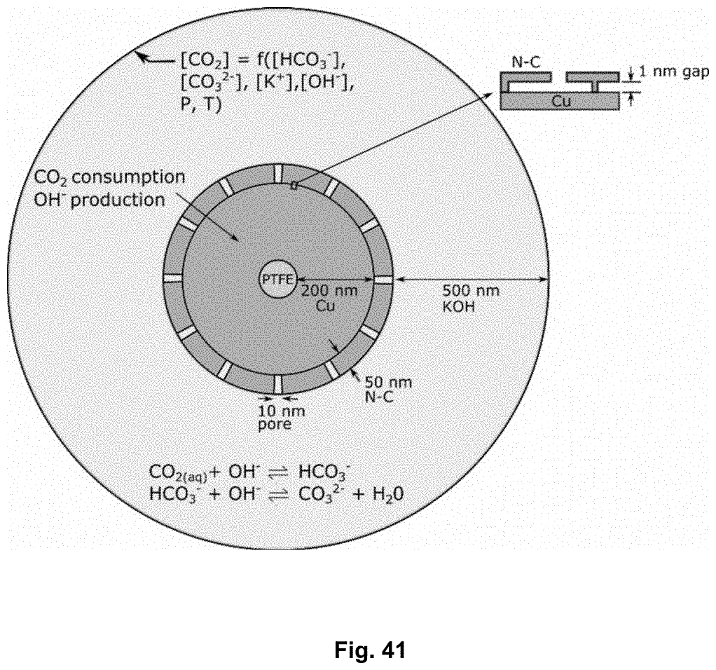

A schematical view of the catalytic system according to some implementations is shown in FIG. 41. In FIG. 41, a cross sectional view of the catalytic system is presented in the center of the drawing. The fibrous hydrophobic substrate includes a PTFE nanofiber. The first layer includes copper nanoparticles and has a thickness of about 20 nm. The second layer of amorphous nitrogen-doped carbon has a thickness of about 50 nm and pores having a diameter of about 10 nm extend through the thickness of this second layer. Confined interlayer spaces are present between the first and the second layers with an interlayer distance of about 1 nm in such confined spaces. Also, referring to FIG. 1f, an interlayer space is represented, where the CO₂ molecules can intercalate, and ethanol can be produced. In FIG. 2a and FIG. 37a,b, a plurality of PTFE nanofibers covered with the first and second layer are shown, which can form, in some implementations, a nanofibers membrane catalytic system. According to some implementations, the second layer of the catalytic system, can include pores as shown in FIG. 38a,b,c,d.

The catalytic system according to the present disclosure can be prepared using any techniques known in the field. In some implementations, the catalytic system can be produced by a sputtering method, such as magnetron sputtering deposition. Hence, in a first step, the copper or copper alloy is sputtered onto the fibrous hydrophobic substrate to form the first layer of copper or copper alloy nanoparticles. A subsequent step can include sputtering the nitrogen-doped carbon onto the first layer to form the second layer of the catalytic system. In some implementations, the first layer can be formed from a copper or copper alloy target, in an argon environment, at a sputtering rate that can vary from about 0.5 Å s⁻¹ to about 1.5 Å s⁻¹. In some implementations, the sputtering rate for forming the first layer can range from about 1 Å s⁻¹ to about 1.5 Å s⁻¹, or from about 1 Å s⁻¹ to about 1.2 Å s⁻¹. Hence, in some implementations, the copper or copper alloy sputtering rate for forming the first layer can be about 0.5, 0.6, 0.7, 0.8, 0.9, 1.0, 1.1, 1.2, 1.3, 1.4, or 1.5 Å s⁻¹. In further implementations, the second layer can be formed from a carbon target (e.g., carbon graphite), in a N₂ and argon environment, at a sputtering rate that can vary from about 0.01 Å s⁻¹ to about 0.1 Å s⁻¹. In some implementations, the sputtering rate for forming the second layer can range from about 0.01 Å s⁻¹ to about 0.07 Å s⁻¹, or from about 0.03 Å s⁻¹ to about 0.07 Å s⁻¹. Hence, in some implementations, the carbon target sputtering rate for forming the second layer can be about 0.01, 0.02, 0.03, 0.04, 0.05, 0.06, 0.07, 0.08, 0.09, or 0.1 Å s⁻¹. The flow rate of the N₂ gas during sputtering of the carbon target can be adjusted to obtain a desired nitrogen atomic percentage in the second layer. In some implementations, carbon sputtering can be performed at a flow rate ratio of N₂ to argon from about 2/20 sccm to about 20/20 sccm (sccm=standard cubic centimetres per minute). In some implementations, the flow rate ratio of N₂ to argon during sputtering of the carbon target can thus be about 2/20, 3/20, 4/20, 5/20, 6/20, 7/20, 8/20, 9/20, 10/20, 11/20, 12/20, 13/20, 14/20, 15/20, 16/20, 17/20, 18/20, 19/20, or 20/20 sccm. In some implementations, the time during which sputtering is performed, either for forming the first layer and/or the second layer, can be adjusted for obtaining a proper layer thickness. For instance, it can be possible to increase the first and/or second layer thickness, at a fixed sputtering rate, by increasing the sputtering period. Hence, a variety of catalytic system can be produced using the present method, by varying at least the nature of the starting material for the first layer (i.e., pure copper or a copper alloy target), the sputtering rates, the sputtering time and/or flow rate of the N₂ gas during sputtering of the carbon target.

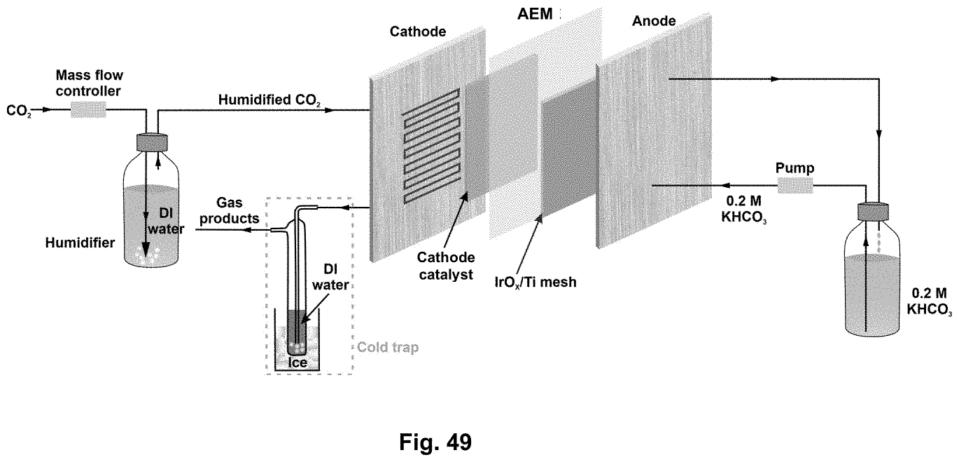

The catalytic system according to the present disclosure can be included in a membrane electrode assembly (MEA) system that can be used to perform electroreduction of carbon dioxide, carbon monoxide, or a combination thereof. In some implementations, one can refer to a “MEA electrolyser”. In some implementations, the MEA system or MEA electrolyser can be used to electrochemically reduce carbon dioxide, carbon monoxide, or a combination thereof, to then produce at least one of ethanol, n-propanol, ethylene, acetate and/or acetic acid, formate and/or formic acid, methane, and hydrogen. In some implementations, CO can be produced from the electroreduction of carbon dioxide using the MEA system. In further implementations, MEA system can particularly be used for the electroreduction of carbon dioxide, carbon monoxide, or a combination thereof, into ethanol. In some implementations, the MEA system or MEA electrolyser can particularly be used to electrochemically reduce carbon dioxide to produce ethanol. FIG. 49 shows an MEA system that include a catalytic system according to some implementations. The MEA system can thus include a cathode side and an anode side, where the cathode side can include the catalytic system of the disclosure (referred to as “cathode catalyst” in the FIG. 49). In this implementation, the catalytic system, or cathode catalyst, can include a PTFE nanofiber membrane where the PTFE nanofibers are coated with a first layer of copper particles and a second layer of amorphous nitrogen-doped carbon as previously discussed. The cathode catalyst can be attached on the cathode side at an edge of the cathode. Generally, the cathode/cathode catalyst assembly is designed to avoid contact of the cathode itself with the electrolyte. In some implementations, the anode side of the MEA can also be provided with an anode catalyst. Different types of catalysts can be used for the anode catalyst, as known in the field. In some implementations, the anode catalyst can include an iridium oxide. The iridium oxide can be supported on titanium mesh. In some implementations, the anode catalyst can include a plurality of IrOₓ/Ti mesh. The anode catalyst (meshes) can be connected to the anode in a conventional manner. In some implementations, an anion exchange membrane (AEM) can be used to separate the cathode and anode compartments of the MEA electrolyser. The anion exchange membrane can be any type of AEM that can be used in CO₂ or CO electrolysers. For instance, Sustainion® membranes can be used in the MEA system.

In some implementations, the MEA system is provided with means to supply a reactant gas including CO₂, CO, or a combination thereof, to the cathode side of the MEA system. In some implementations, the reactant gas can be flowed through a humidifier before being supplied to the cathode compartment. The humidifier can for instance include deionized water. Hence, a humidified reactant gas can be supplied to MEA system, and then be contacted with the catalytic system of the present disclosure, to allow electroreduction of CO₂ and/or CO.

According to some implementations, the present disclosure thus further relates to a method for the electrochemical reduction of CO₂, CO, or a combination thereof, involving the use of the catalytic system or of the MEA system described herein. The method includes contacting a reactant gas including carbon dioxide, carbon monoxide, or a combination thereof, in the presence of an electrolyte, with a cathode including the catalytic system of the present disclosure and applying a voltage to provide a current density to cause the CO₂ and/or CO in the reactant gas contacting the cathode, to be electrochemically reduced. As mentioned above, the gas can preferably be humidified before contacting with the cathode. The electrolyte that can be used for electroreduction of CO₂ and/or CO can be an alkaline aqueous solution, preferably including a strong base. In some implementations, the electrolyte can include a KHCO₃ or a KOH aqueous solution. The voltage applied for the electroreduction reaction can be determined and optimized to enhance selectivity towards a desired product

In some implementations, the method can particularly be used for the production of ethanol and can be performed by contacting the reactant gas including carbon dioxide, carbon monoxide, or a combination thereof, in the presence of an electrolyte, with a cathode including the catalytic system as defined in the present disclosure, followed by applying a voltage to provide a current density to cause the carbon dioxide, carbon monoxide, or the combination thereof in the reactant gas contacting the cathode, to be electrochemically converted into ethanol. The gas can be humidified before contacting with the cathode. The electrolyte can be an alkaline aqueous solution, preferably including a strong base. In some implementations, the electrolyte can include a KHCO₃ or a KOH aqueous solution. The voltage for the electroreduction reaction can be determined and optimized to enhance selectivity towards ethanol. For example, the voltage that can be applied for electrochemically reducing CO₂ into ethanol can be from about −3.0 to about −4.0 volts.

In some implementations, the reactant gas that is subjected to electroreduction can be a raw gas, an enriched gas, a diluted gas or a pure gas from many different CO₂ and/or CO sources. In some implementations, the electrochemical reduction method using the catalytic system of the present disclosure, can be employed for reducing CO₂ and/or CO present in an exhaust gas produced from industrial and/or agricultural processes. For instance, the reactant gas that can be treated in the electroreduction method disclosed herein, can include a gas resulting from the combustion of fossil fuels, a flue gas from stacks, an off-gas (i.e., a gas emitted as the by-product of a chemical process) or a biogenic CO₂ gas resulting from the combustion, harvest, digestion, fermentation, decomposition or processing of biologically based materials other than fossil fuels. In some implementations, the reactant gas can be pure or enriched CO₂ derived from any of the above-mentioned sources and can be produced from a raw CO₂-containing gas by various methods such as absorption-desorption (e.g., amine scrubbing), adsorption-desorption (e.g., using adsorbents capable to catch and release CO₂), among others. In some implementations, the CO₂-containing gas can be captured from the atmosphere (air) using various technologies (e.g., direct air capture). In some implementations, the reactant gas, that can be derived from any of the above-mentioned sources, including from air, can be diluted before electroreduction. In some implementations, pure CO₂ derived from any of the above-mentioned sources can be employed in the electroreduction process. In some implementations, a CO-containing gas can be used as the reactant gas. In some implementations, the CO-containing gas can be obtained from a CO₂-containing gas. For instance, the reactant gas can include CO which results from the reduction of CO₂. In some implementations, the reactant gas can include both CO₂ and CO.

### EXAMPLES & EXPERIMENTATION & FINDINGS

The following section relates to various experiments that were conducted in the course of this work.

### 1—Methods

Chemicals. Copper target (99.999%) and carbon graphite target (99.999%) were purchased from Kurt J. Lesker company (Certain commercial equipment, instruments, or materials are identified herein in order to specify the experimental procedure adequately. Such identification is not intended to imply recommendation or endorsement by the National Institute of Standards and Technology, nor is it intended to imply that the materials or equipment identified are necessarily the best available for the purpose). Potassium hydroxide (KOH) was purchased from Caledon Laboratory Chemical. Iridium (III) chloride hydrate (IrCl₃-xH₂O, 99.9%) and potassium bicarbonate (KHCO₃, 99.5%) were purchased from Sigma-Aldrich. Anion exchange membrane (Fumasep FAB-PK-130), gas diffusion layer (GDL, Freudenberg H14C9), and titanium mesh were received from Fuel Cell Store. Sustainion® anion-exchange membrane (AEM) was received from Dioxide Materials; the membrane was activated in 1 M KOH aqueous solution for 24 hours and then washed with water before use. PTFE membrane with an average pore size of 450 nm was purchased from Beijing Zhongxingweiye Instrument Co., Ltd. Ni foam (1.6 mm thickness) was purchased from MTI Corporation. All chemicals were used as received. All aqueous solutions were prepared using deionized (DI) water with a resistivity of 18.2 MΩcm⁻¹.

Electrodes. All the cathodes were prepared using a magnetron sputtering system. Typically, a Cu cathode was prepared by sputtering 200 nm Cu catalyst (Cu target, sputtering rate: ˜1.1 Å s⁻¹) on a piece of PTFE membrane. The mass loading of Cu on PTFE membrane is 0.19 mg cm⁻². By sputtering 50 nm of the N—C layer or the carbon layer (carbon graphite target, sputtering rate: ˜0.05 Å s⁻¹) on sputtered Cu catalysts supported by PTFE, we can further obtain the N—C/Cu and C/Cu cathodes, respectively. N—C layers with different nitrogen contents were prepared by adjusting the flow rate ratio of N₂ to Ar. For deposition of carbon, 26%, 34%, and 39% N—C layers on sputtered Cu catalysts, the flow rate ratios of N₂ to Ar are set to be 0/20, 2/20, 6/20, and 20/20 (sccm=standard cubic centimetres per minute), respectively. Similarly, the 34% N—C gas diffusion electrode (GDE) was prepared by sputtering 50 nm of the N—C layer onto the GDL.

In flow cell, Ag/AgCl reference electrode (3 M KCl, BASi) and Ni foam were used as the reference electrode and anode, respectively. In MEA system, the iridium oxide supported on titanium mesh (IrOx/Ti mesh) used as the anode catalyst was prepared by a reported dip coating and thermal decomposition method (ref. 39).

Structural and compositional analyses. SEM images and the corresponding EDX elemental mapping were taken using Hitachi FE-SEM SU5000 microscope. HAADF-STEM images, and the corresponding EDX and electron energy loss spectroscopy (EELS) elemental mapping were taken using a Hitachi HF-3300 microscope at 300 kV and aberration-corrected FEI Titan 80-300 kV TEM/STEM microscope at 300 kV, with a probe convergence angle of 30 mrad and a large inner collection angle of 65 mrad to provide a nominal image solution of 0.7 Å. For STEM/TEM imaging, an ultrathin slice (˜100 nm) was prepared using the Leica UM7 ultramicrotome (Leica Microsystems Inc. in Buffalo Grove, Ill.). The slice was then transferred to a 100-mesh nickel grid for characterization. Cross-sectional SEM image and EDX elemental mapping was performed using Hitachi Dual-beam FIB-SEM NB5000. Structural characterization of cathodes was obtained using XRD (MiniFlex600) with Cu-Kα radiation. The surface compositions of cathodes were determined by XPS (model 5600, Perkin-Elmer) using a monochromatic aluminum X-ray source. In situ Raman measurements were operated using a Renishaw in Via Raman Microscope in a modified flow cell and a water immersion objective (63×) with a 785 nm laser. XAS measurement were conducted at 9BM beamline at Advanced Photon Source (APS, Argonne national laboratory, IL). Ex-situ XAS measurements were carried out at the BL731 beamline at the Advanced Light Source (ALS, Lawrence Berkeley National Laboratory, CA) and the SXRMB beamline at the Canadian Light Source. Athena and Artemis software included in a standard IFEFFIT package were used to process XAS data (ref. 40). WAXS measurements were carried out in transmission geometry at the CMS beamline of the National Synchrotron Light Source II (NSLS-II), a U.S. Department of Energy (DOE) office of the Science User Facility operated for the DOE Office of Science by Brookhaven National Laboratory. Samples were measured with an imaging detector at a distance of 0.177 m using X-ray wavelength of 0.729 Å. Nika software package was used to sector average the 2D WAXS images (ref. 41). Data plotting was done in Igor Pro (Wavemetrics, Inc., Lake Oswego, Oreg., USA).

Electrochemical measurements. In the flow cell, the electrochemical measurements were conducted in the three-electrode system at an electrochemical station (AUT50783). Prepared cathodes, anion exchange membrane, and nickel foam were positioned and clamped together via PTFE gaskets. Here nickel foam was used as the anode for oxygen evolution reaction (OER) in flow cell as nickel is a good OER catalyst in alkaline environment (ref. 42). 30 ml of electrolyte (1 M KOH aqueous solution) was introduced into the anode chamber between anode and membrane, as well as the cathode chamber between membrane and cathode, respectively. The electrolytes in cathode and anode were circulated by two pumps at the rate of 10 mL min⁻¹. Meanwhile, CO₂ gas (Linde, 99.99%) was continuously supplied to gas chamber located at the back side of cathode at the rate of 50 mL min⁻¹. Through the pore of the cathode, gas could diffuse into the interface between cathode and electrolyte. The performance of cathodes was evaluated by performing constant-current electrolysis. All potentials were measured against an Ag/AgCl reference electrode (3 M KCl, BASi). In isotope-labelling experiment, the procedure was the same to the above experiment condition, except that ¹³CO₂ gas (Sigma-Aldrich, 99 atom % ¹³C) was used as the supply gas.

Gas and liquid products were analyzed using gas chromatograph (PerkinElmer Clarus 600) equipped with thermal conductivity and flame ionization detectors, and NMR spectrometer (Agilent DD2 600 MHz) by taking dimethylsulfoxide (DMSO) as an internal standard, respectively. All the potentials were converted to values with reference to RHE using:

E_{RHE}=E_{Ag/AgCl}+0.210V+0.0591×pH

The ohmic loss between the working and reference electrodes was measured through electrochemical impedance spectroscopy (EIS) technique at the beginning of the electrolysis and 95% iR compensation was applied to correct the potentials manually.

Cu_{ECSA} in catalysts was determined using Pd underpotential deposition in flow cell. N₂-saturated solution of 100 mM HClO₄+1 mM Pd(ClO₄)₂ is used as the electrolyte. The cathode was held at −0.081 V_{RHE} for 60 s and then cyclic voltammetry (CV) was recorded between −0.281 and 0.239 V_{RHE} at 5 mV s⁻¹. Pt foil was used as the anode. N₂ (Linde, 99.998%) was continuously supplied to gas chamber of the flow cell. The electrolyte was not circulated during the CV measurement. The Cu_{ECSA} in the catalyst is calculated from the charge associated with 2e⁻ oxidation of monolayer of Pd adatoms coverage over Cu surface with a conversion factor of 310 μC cm⁻² (ref. 43).

The MEA was a complete 5 cm² CO₂ electrolyzer (SKU: 68732), which was purchased from Dioxide Materials. The cathode catalyst (2.25 cm by 2.25 cm) was attached on the cathode side by the copper tape at the edge of the electrode and Kapton tapes was then attached on the top of copper tape to avoid its contact with the membrane/electrolyte. The activated Sustainion® membrane (3 cm×3 cm) and five pieces of IrOₓ/Ti mesh anode catalysts (2.25 cm by 2.25 cm) were put on the top of the cathode successively and then assembled together in an MEA as shown in FIG. 49. In anode side, 0.2 M KHCO₃ aqueous solution was used as the anolyte and was circulated using a pump at the rate of 10 mL In cathode side, CO₂ gas (80 mL min⁻¹) continuously flowed to the humidifier with deionized (DI) water and was then supplied to the cathode chamber of MEA. The performance of the catalysts in MEA system was evaluated by applying different full-cell potentials in two-electrode system at the electrochemical station (AUT50783) equipped with a current boost (10 Å). The gas products were collected and tested by gas chromatograph after the products from cathode side went through a simplified cold trap (FIG. 49). Due to the liquid product crossover, the FEs of liquid products were calculated based on the total amount of the products collected in anode and cathode sides during the same period.

Calculation for energy conversion efficiency. In flow cell, ethanol energy conversion efficiency is calculated for the half-cell in cathode (EE_{cathodic half-cell}). The overpotential of oxygen evolution is assumed to be 0. The ethanol EE_{cathodic half-cell} can be calculated as follows (ref. 6):

$${EE}_{cathodic half - cell} = \frac{( 1.23 + ( - {E}_{ethanol} ) ) \times {FE}_{ethanol}}{( 1.23 + ( - {E}_{applied} ) )} ,$$

where E_{applied} is the potential used in the experiment, FE ₑₜₕₐₙₒₗ is the measured Faradaic efficiency of ethanol in percentage, and Eₑₜₕₐₙₒₗ=0.09 V_{RHE} for CO₂RR (ref. 44).

In MEA system, ethanol energy efficiency is calculated for full cell:

$${EE}_{full - cell} = \frac{( 1.23 + ( - {E}_{ethanol} ) ) \times {FE}_{ethanol}}{- {E}_{full - cell appied}} ,$$

where E_{full-cell appied} is the full-cell voltage applied in MEA system.

Theoretical methods. In this work, all the DFT calculations were carried out with a periodic slab model using the Vienna ab initio simulation program (VASP) (refs. 45-48). The generalized gradient approximation (GGA) was used with the Perdew-Burke-Ernzerhof (PBE) exchange-correlation functional (ref. 49). The projector-augmented wave (PAW) method (refs. 50-51) was utilized to describe the electron-ion interactions, and the cut-off energy for the plane-wave basis set was 450 eV. In order to illustrate the long-range dispersion interactions between the adsorbates and catalysts, the D3 correction method by Grimme et al. was employed (ref. 52). Brillouin zone integration was accomplished using a 3×3×1 Monkhorst-Pack k-point mesh.

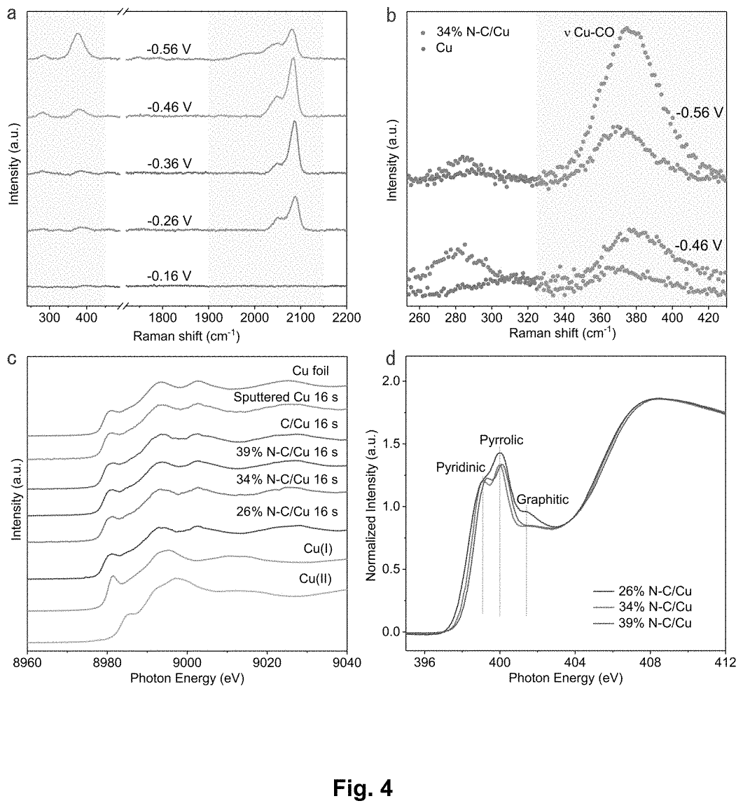

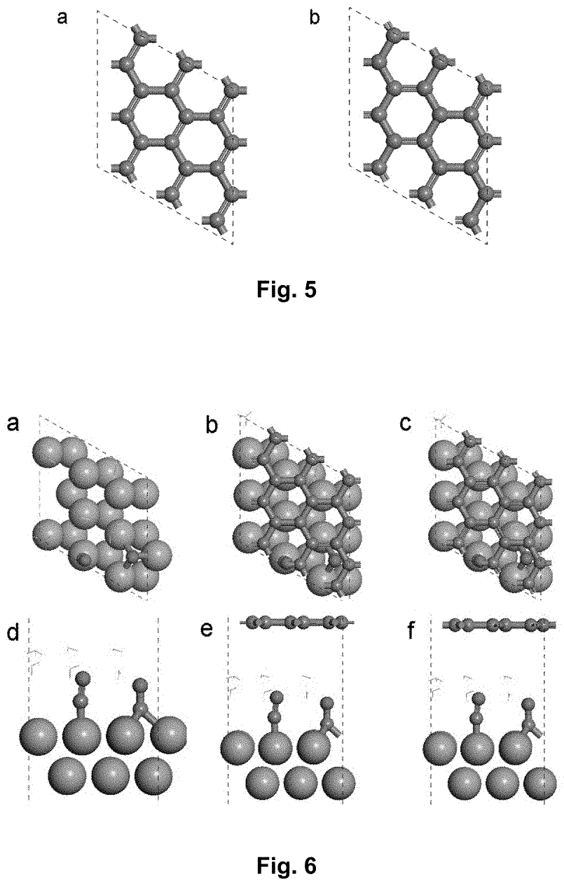

For the modelling of copper, the crystal structure was optimized, and the equilibrium lattice constants were found to be α_{Cu}=3.631 Å. A 4-layer model was used with p(3×3) super cell with the 2 upper layers relaxed and 2 lower layers fixed. All the adsorption geometries were optimized using a force-based conjugate gradient algorithm, while transition states (TSs) were located with a constrained minimization technique (refs. 53-55). At all intermediate and transition states, one charged layer of water molecules was added to the surface to take the combined effects of field and solvation into account: six water molecules are added near the surface, with three facing toward the surface, and three parallel with the surface (ref. 56). To consider the effect from the confinement of carbon and nitrogen-doped carbon on Cu, one layer of graphene or nitrogen-doped graphene was added on Cu surface as shown in FIG. 5.

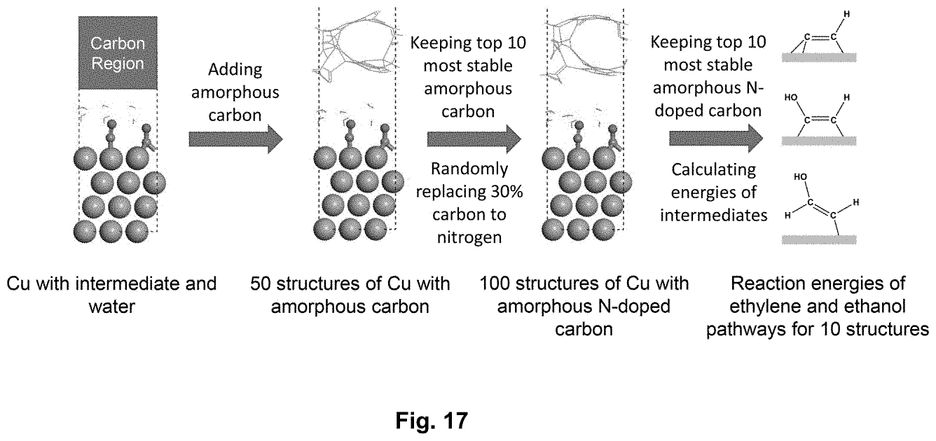

A sampling framework based on the amorphous study by Deringer et al. (ref. 57) was further developed. 50 amorphous carbon and 100 amorphous N-doped carbon structures were investigated using the pipeline (FIG. 17).

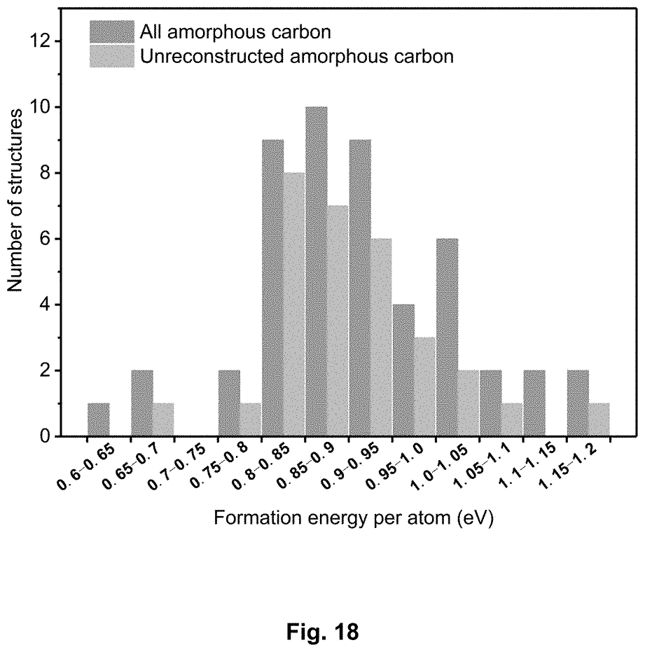

The pipeline was started with the structure of Cu surface with intermediate and water (Structure-1). We then added amorphous carbon structures on the surface of Structure-1 and allow DFT to fully relax the amorphous structures and water molecules. All the fifteen amorphous structures are considered from the amorphous study (in folder “DFT_relaxed_216 at”) by Deringer et al. (ref. 57). The formation energy per atom distribution of the optimized amorphous carbon are shown in FIG. 18. We checked the energy distribution of the amorphous carbon structures and removed reconstructed structures such as structures with proton transferred from water to amorphous carbon.

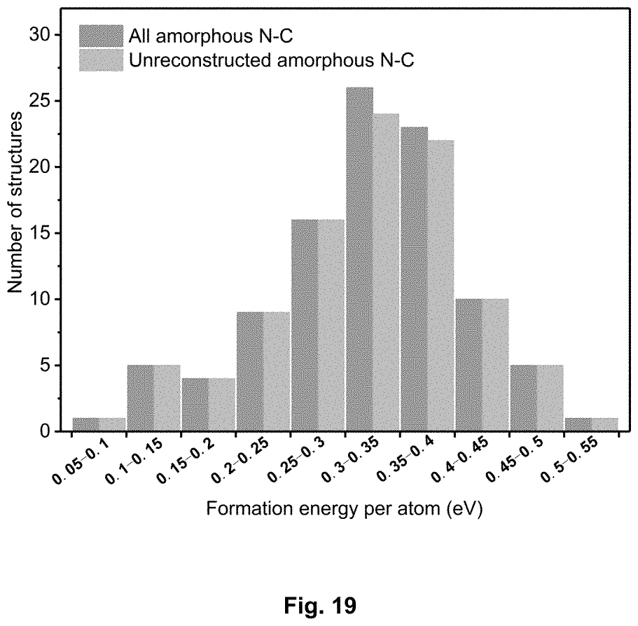

The top 10 most stable unreconstructed amorphous carbon structures were kept, and for each amorphous carbon structure, we randomly replaced 30% carbon with nitrogen ten times. This process generated 100 amorphous N-doped carbon structures, and the formation energy per atom distribution of the 100 structures are shown in FIG. 19. We then chose top 10 most stable amorphous N-doped carbon structures (Table 7) and calculated the reaction energies of ethanol and ethylene pathways (Table 8). The overall preference of the pathways represents the contribution from all of the structures. The average reaction energies of ethylene and ethanol pathway are 0.01 eV and −0.12 eV, respectively, indicating that confinement due to amorphous N-doped carbon promotes ethanol selectivity.

Local species concentration modelling. The system was modeled as a two-dimensional domain with 200 nm thickness of Cu and 50 nm thickness of porous N—C layer according to the catalyst, as well as electrolyte sub-domains (FIG. 38). The local concentrations of CO₂, CO₃²⁻, HCO₃⁻, OH⁻, H⁺, and H₂O in an electrolyte solution under CO₂RR conditions were modelled in COMSOL 5.4 (COMSOL Multiphysics, Stockholm, Sweden) using the Transport of Dilute Species physics with values reported in Table 9. This model, based on previous papers (refs. 6, 58, 59), accounts for the acid-base carbonate equilibria, as well as CO₂ reduction via electrocatalysis in an electrolyte solution (1 M KOH). The quantity of dissolved CO₂ in solution is determined by the temperature, pressure, and solution salinity. Assuming CO₂ acts as an ideal gas, the dissolved amount is given by Henry's Law (refs. 60, 61), and the solubility is further diminished due to high concentration of ions in solutions according to the Sechenov Equation (ref. 62). CO₂, CO₃²⁻, HCO₃⁻, OH⁻, H⁺, and H₂O are all in equilibrium in solution according to the acid-base equilibria (refs. 63-66) with flux due to Fickian diffusion (ref. 67), as well as CO₂ reduction and OH⁻ production (refs. 68, 69) for a current density of 300 mA cm⁻². A time-dependent study was performed to simulate species evolution toward steady state. At the perimeter of the outer boundary, the CO₂ concentration was specified according to Henry's Law and the Sechenov effect, with 1 M KOH equilibrium concentrations imposed for CO₃²⁻, HCO₃⁻, and OH⁻. The inner Cu domain is modeled as solid, on the surface of which the CO₂ was reduced and OH⁻ was produced, and the N—C domain is porous—with discrete 10 nm nanopores as well—all of which utilize Bruggeman effective diffusivity (refs. 70-72). We set a ˜1 nm gap between Cu layer and N—C layer based on the actual N—C/Cu catalyst. The case for no N—C layer was modeled by excluding the N—C domain with all other parameters the same.

### 2—DFT Calculations

The CO dimerization reaction (FIG. 1a, and FIGS. 5-9, and Table 2), a key step for C₂₊ production, was investigated on three structures: a N—C layer on the Cu surface (N—C/Cu); a carbon layer on the Cu surface (C/Cu); and Cu. N—C/Cu has the lowest barrier and enthalpy change for CO dimerization compared to C/Cu and Cu (FIG. 1b), suggesting that N—C/Cu will deliver the highest selectivity to C₂₊ products. In contrast, C/Cu has worse CO dimerization kinetics compared to bare Cu, indicating that the carbon cover on Cu will work against C—C coupling for C₂₊ products.

To understand how the N—C layer affected CO dimerization, electron density difference plots were also generated for N—C/Cu and C/Cu with two adsorbed *CO in solution (FIGS. 1c and d). The N—C layer loses electrons (blue) and the adsorbed *CO gains electrons (yellow), whereas there is no obvious electron transfer between carbon layer and adsorbed *CO, suggesting that the N—C layer is beneficial to electron transfer to adsorbed *CO on Cu, and that it thus promotes the generation of C—C coupled intermediate.

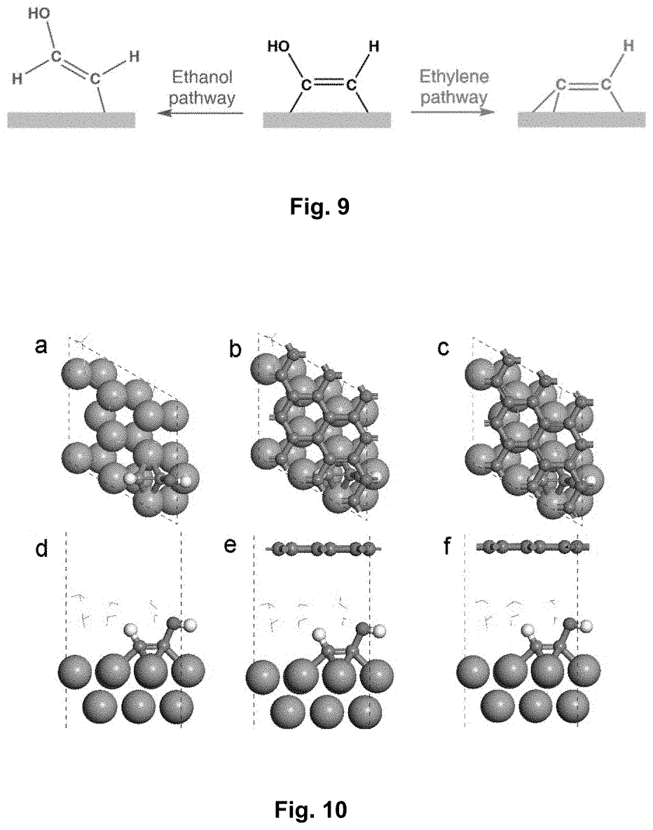

HOCCH* is the key intermediate that branches the ethylene pathway and the ethanol pathway (FIG. 9). Therefore, the reaction energies of HOCCH* to CCH* (ethylene pathway) and HOCCH* to HOCHCH* (ethanol pathway) were further calculated to understand the effect of different confining materials on the C₂ product distribution (FIGS. 10-13 and Tables 3-6). Compared to bare Cu, the C/Cu and N—C/Cu catalysts improve ethanol selectivity vs. ethylene (FIG. 1e and Table 3), which is ascribed to the confinement effect in the stabilization of the C—O bond of HOCCH*, which leads to a suppression of the deoxygenation process. Herein, the distances between Cu and graphene or nitrogen-doped graphene layer (d_{N—C/Cu}) were optimized with DFT (Table 7 and FIGS. 14-16) and the results showed that ethanol selectivity can be promoted in N—C/Cu with the d_{N—C/Cu} range of 6.42 Å to 9.42 Å compared to the case of Cu alone. Additionally, the reaction energies of ethanol and ethylene pathways were calculated based on amorphous N-doped carbon/Cu (amorphous N—C/Cu) (FIGS. 14-19 and Tables 8, 9). Amorphous N—C/Cu also improves ethanol selectivity vs. ethylene compared to bare Cu (FIG. 1e). Interestingly, the ethanol pathway on both crystalline N-C/Cu and amorphous N—C/Cu is favored thermodynamically, whereas the ethylene pathway is suppressed, suggesting that C—O bond-breaking from HOCCH* is prevented on both crystalline N-C/Cu and amorphous N—C/Cu. These results suggest that N—C/Cu has the potential to generate an increased selectivity to ethanol (FIG. 1f).

### 3—Catalyst Synthesis and Characterization

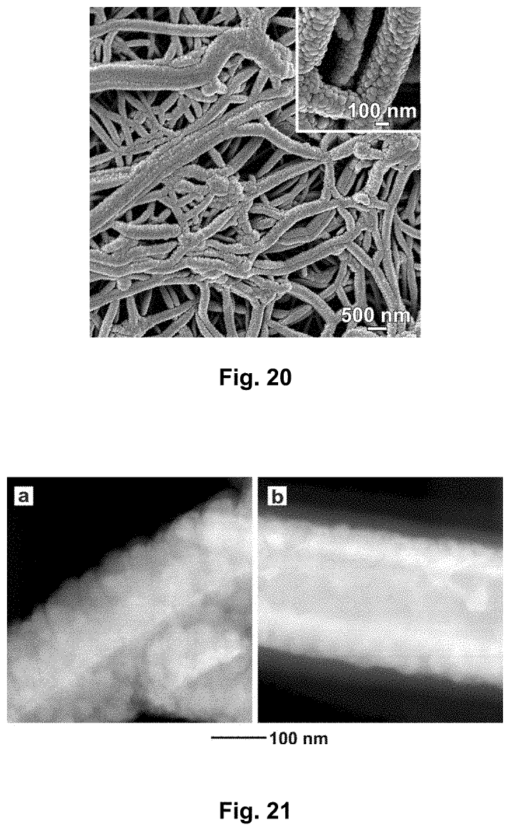

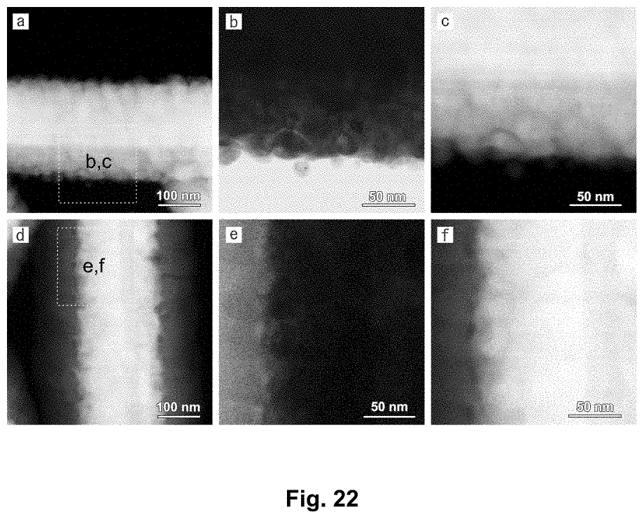

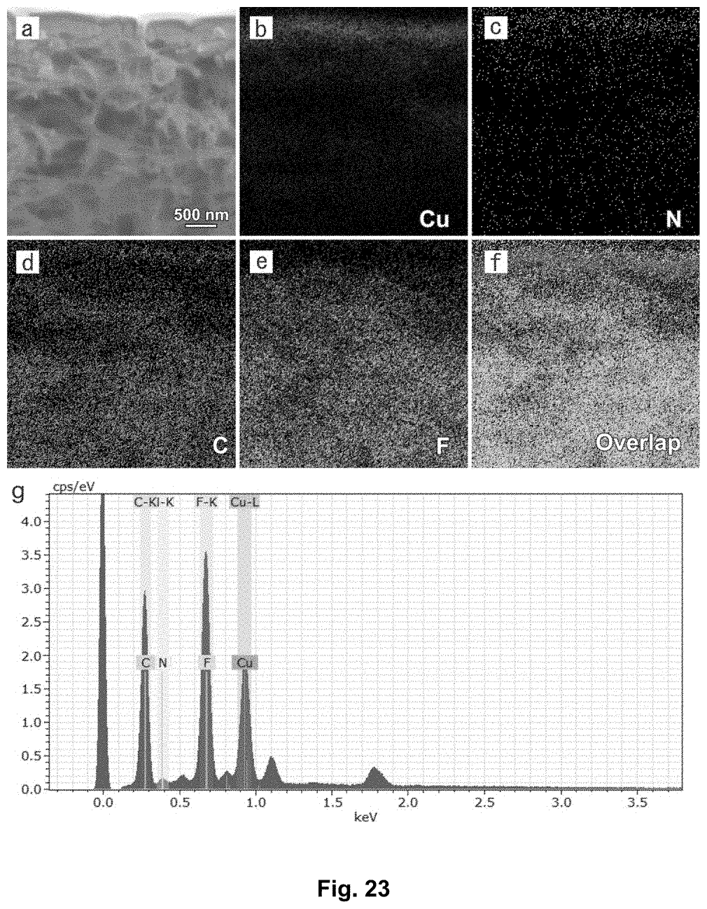

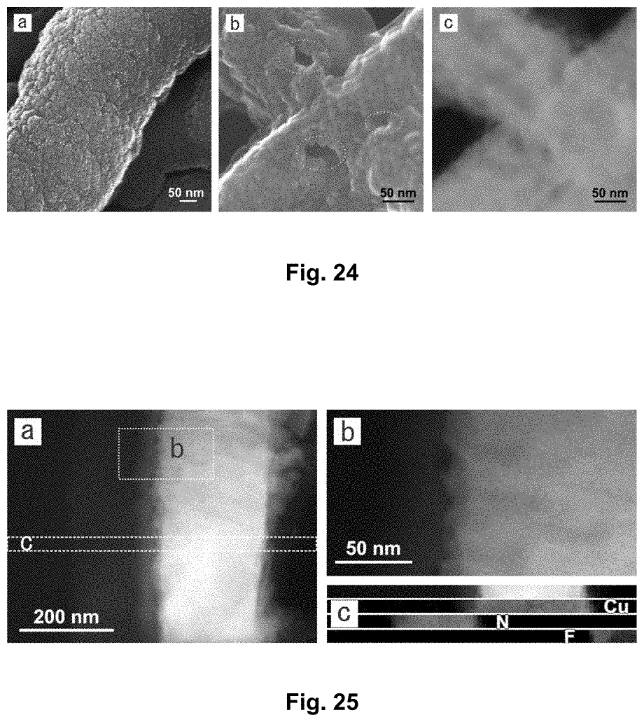

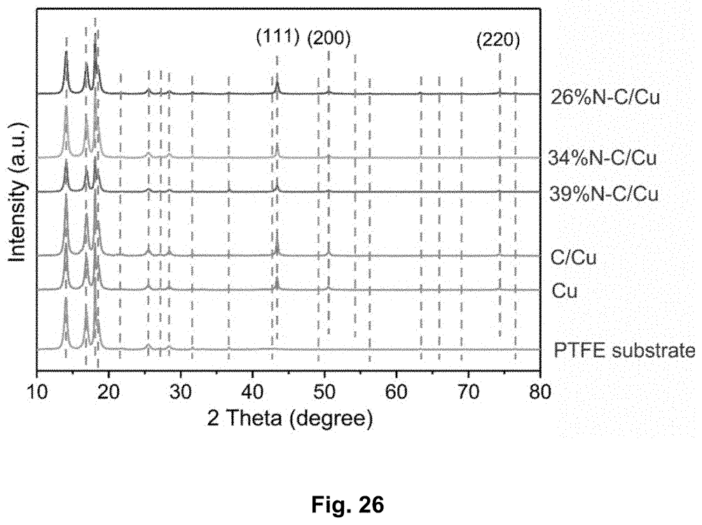

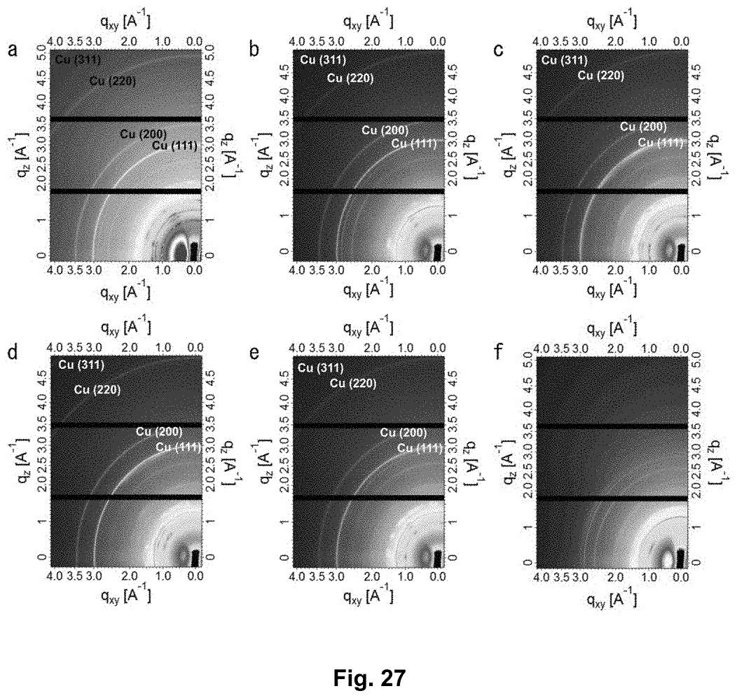

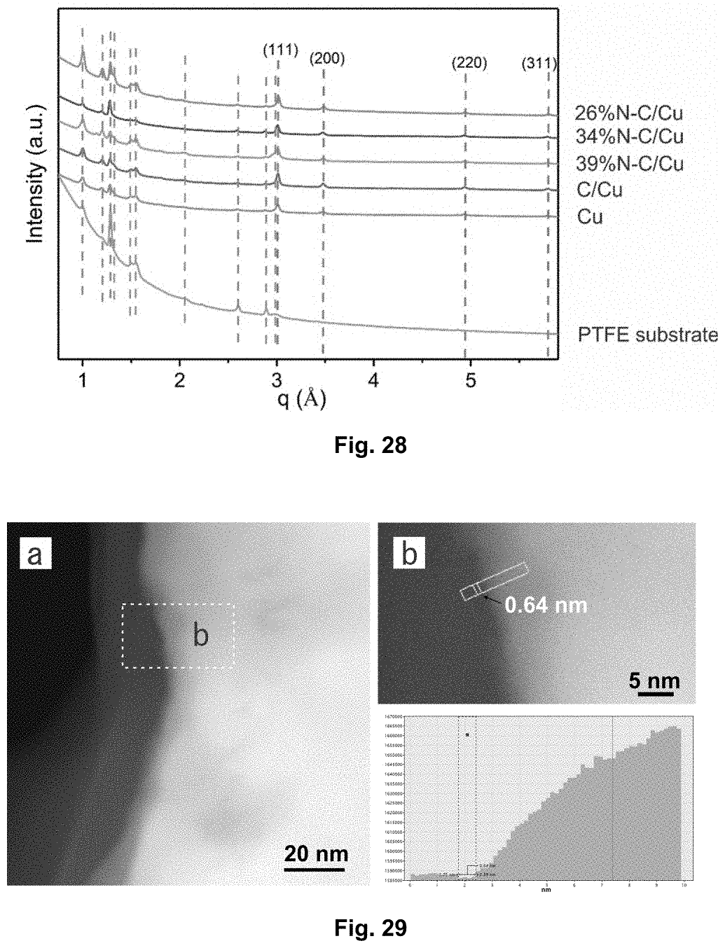

N—C/Cu catalysts were fabricated via sputter deposition of a layer of Cu nanoparticles on the surface of polytetrafluoroethylene (PTFE) nanofibers (FIGS. 20-22), followed by the sputter deposition of a layer of N—C on the surface of sputtered Cu nanoparticles (FIG. 2a and FIGS. 21-24). Energy-dispersive X-ray spectroscopy (EDX) elemental mapping shows a uniform distribution of Cu, N, and C on PTFE nanofibers (FIG. 2b). Electron microscopy investigations confirm that the N—C layer coated on the Cu (FIG. 2c-e and FIG. 25). Powder X-ray diffraction (XRD) and transmission wide angle X-ray scattering (WAXS) data for this electrode demonstrate the existence of Cu; there is no observable peak or ring for the N—C layer, indicating an amorphous structure of the N—C layer (FIGS. 26-28). The N—C layer was confirmed by high-resolution X-ray photoelectron spectroscopy (XPS) C1s and N1s spectra (FIGS. 2f and g). The deconvolved C1s peak shows graphitic carbon and the existence of nitrogen atoms (ref. ₂₂). The deconvolved N₁s peak shows that the primary form of N is pyridinic-N(ref. 23) and the atomic percentage of nitrogen in the N—C layer is approximately 34% determined by XPS (denoted as 34% N—C).

Analysis of HAADF-STEM images of microtomed 34% N—C/Cu catalyst demonstrates that there are regions in which a gap is present between the Cu layer and the N—C layer; and there exist other regions in which these layers touch one another (FIG. 2h and FIG. 29a). These images are acquired with a convergence angle of 30 mrad and with an inner collection angle of 65 mrad of a HAADF detector. The HAADF image intensity is approximately proportional to the atomic number Z (refs. 1,7) of the elements (ref. 24) and these images thus can be used to differentiate the Cu and N—C layers. The reduced contrast between the Cu and N—C layer indicates the presence of a gap between these layers; and the intensity profile of this reduced region thus is used for estimating the gap width. In the gap regions, the distance between Cu layers and N—C layers determined is typically less than 1 nm (FIG. 2i and FIG. 29b). This structural analysis of ultrathin slice provides overall guidance to evaluate the gap width, but not an absolute value. Nevertheless, the method can show that, for the range of gap widths estimated, the gap regions can act as nanoreactors.

### 4—Investigation of CO₂ Electroreduction

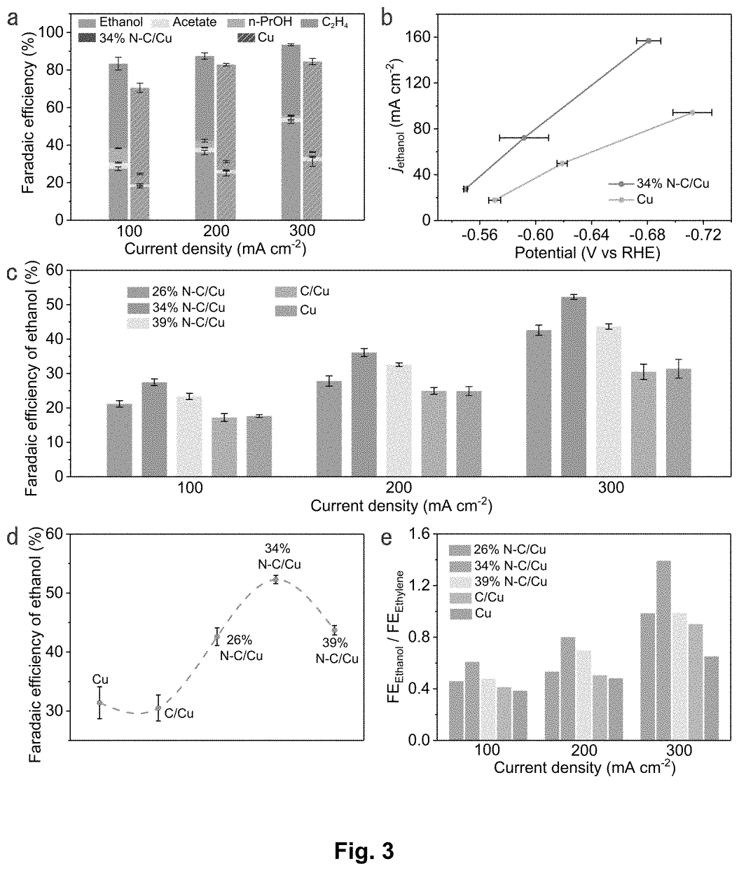

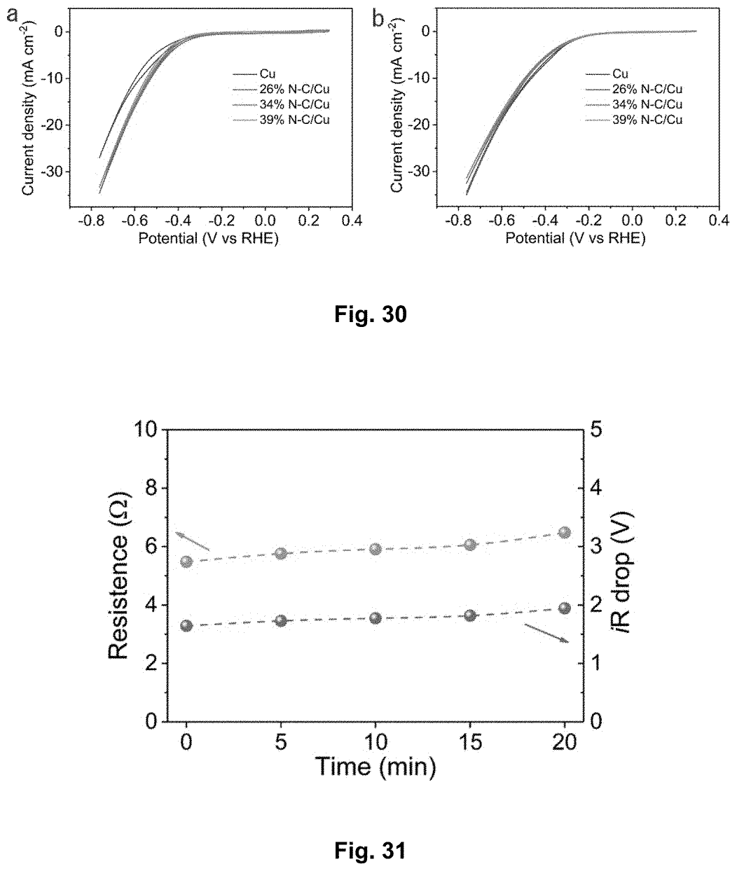

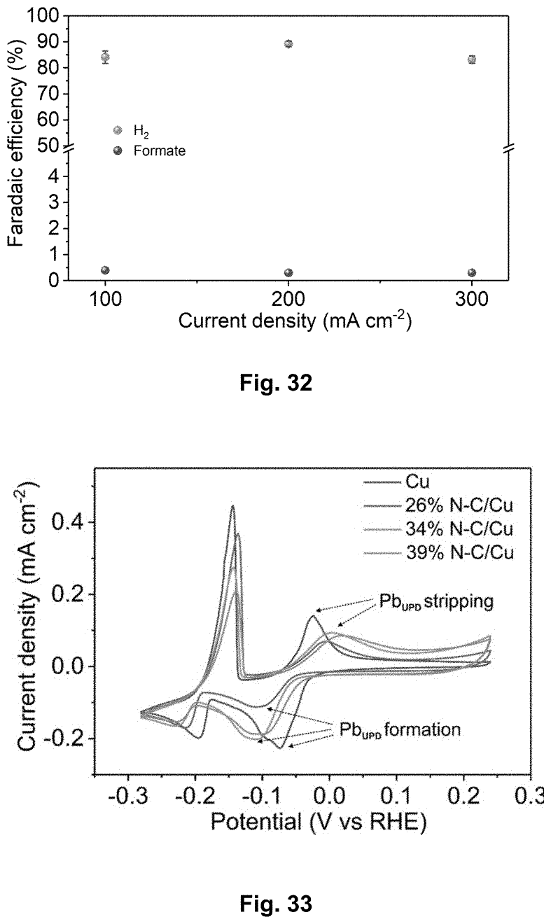

The N—C/Cu electrode was electrochemically tested (FIG. 30) in a flow cell reactor, a configuration similar to that used in a previous report (ref. 25). FIG. 3a shows the FEs for C₂₊ products on the 34% N—C/Cu catalyst in the current density range of 100 to 300 mA cm⁻² in 1 M KOH electrolyte. Both FEs of C₂₊ products and ethanol on the 34% N—C/Cu catalyst are higher than that on the bare Cu control (Table 10), in agreement with the DFT prediction.

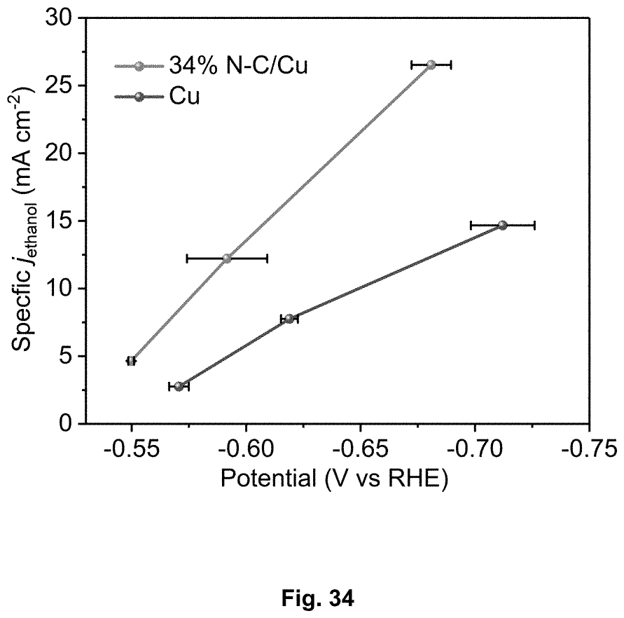

Under a current density of 300 mA cm⁻², the total C₂₊ FE on 34% N—C/Cu is up to 93% and an ethanol FE of (52±1) % is achieved with a conversion rate of (156±3) mA cm⁻² at −0.68 V_{RHE} after ohmic loss correction (FIG. 3b and FIG. 31); this represents an ethanol cathodic EE of 31%. In addition, we note that the H2 FE on 34% N—C/Cu is lower than that on bare Cu (Table 10), also in agreement with DFT calculations (Table 11). We also evaluated the CO₂RR performance on a bare 34% N—C layer; only H2 with FE up to 80-90% could be detected (FIG. 34): there was no ethanol detectable in the electrolyte following CO₂RR, indicating that the ultrathin N—C layer does not, on its own, catalyze CO₂RR to ethanol.

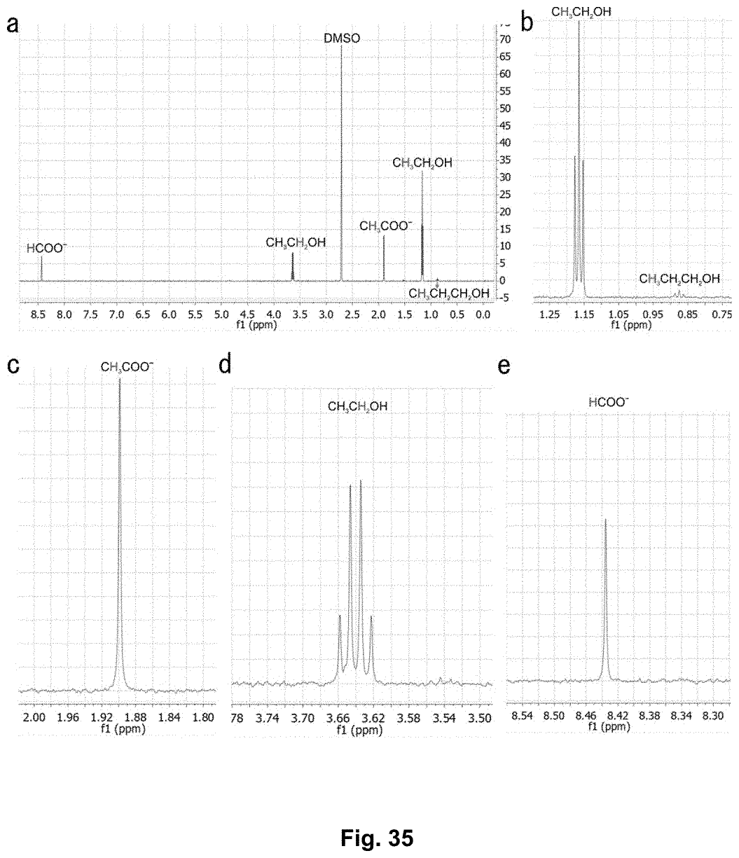

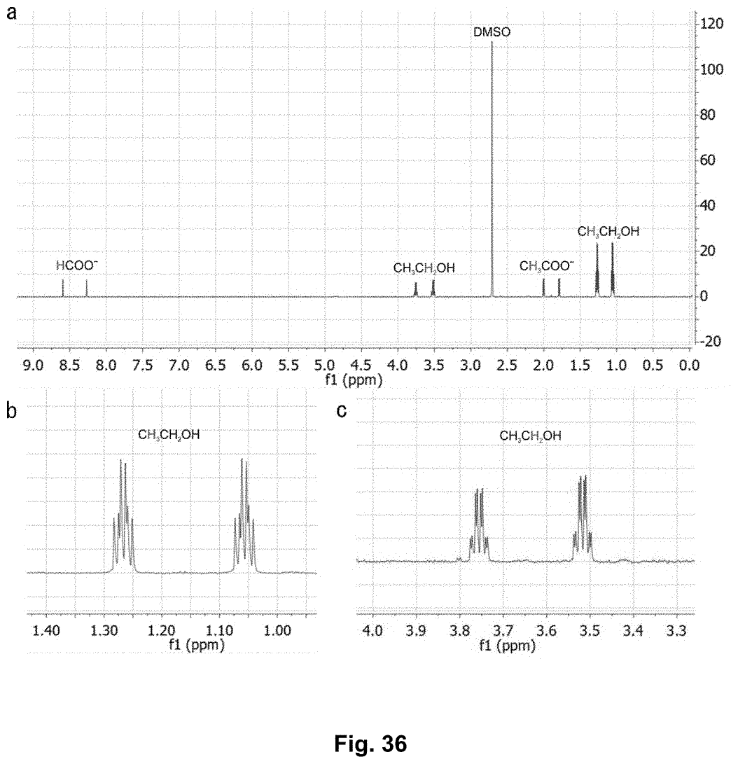

The electrochemically active area of Cu (Cu_{ECSA}) in N—C/Cu and Cu catalysts was estimated using Pb underpotential deposition (Pb_{UPD}) (FIG. 33 and Table 12). We normalized the partial ethanol current density by Cu_{ECSA} to compare intrinsic activity (FIG. 34) and found that, under optimal ethanol conditions (300 mA cm⁻²), the Cu_{ECSA}-normalized partial ethanol current density on 34% N—C/Cu is 26.6 mA cm⁻², which is 1.8 times higher than that on Cu. We further performed isotope-labelling experiments with ¹³CO₂ and found that ethanol was indeed produced via CO₂RR, rather than from contaminants (FIGS. 35 and 36).

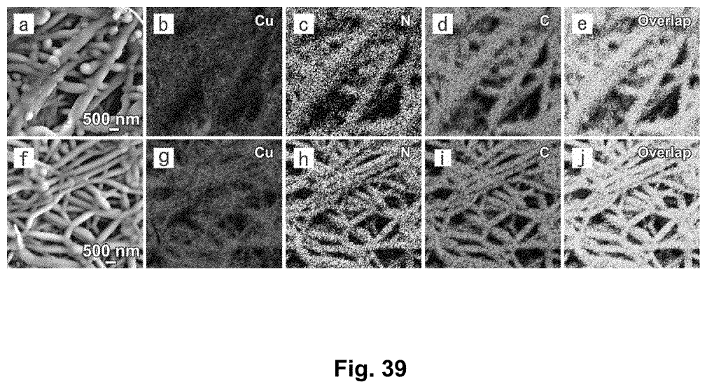

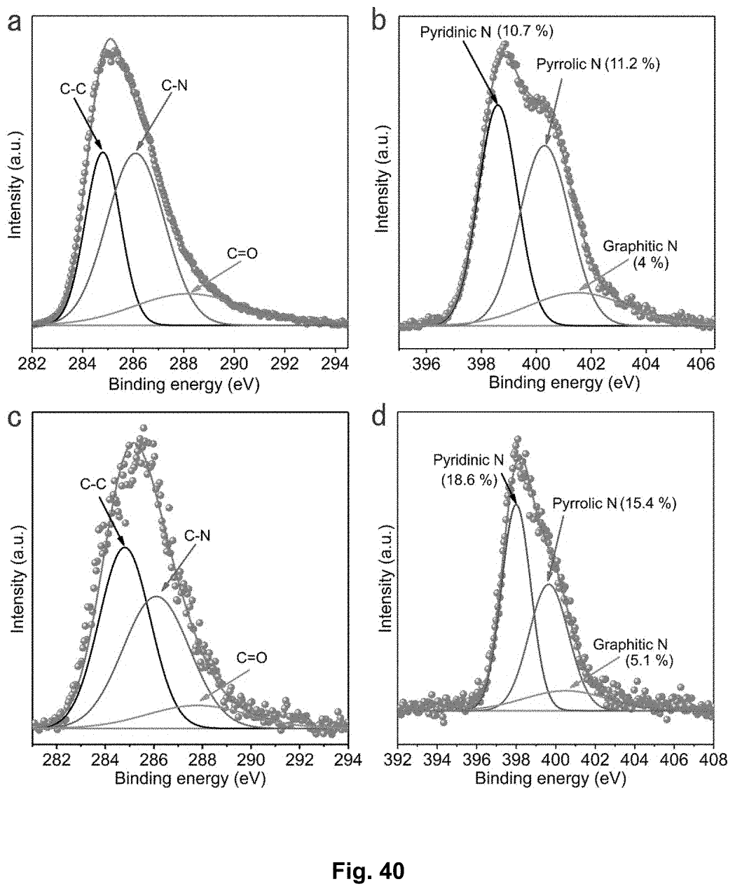

To explore the effects of the N—C layer on the performance of CO₂RR, we also prepared 26% N—C/Cu, 39% N—C/Cu, and C/Cu on PTFE via similar sputtering methods (FIGS. 37-40) and measured their CO₂RR performance for comparison (FIG. 3c-e). Under the same current densities, 26% N—C/Cu and 39% N—C/Cu catalysts also deliver higher C₂₊ FE than Cu catalysts, whereas the C/Cu catalyst shows a lower C₂₊ FE compared to the Cu catalyst (Table 10), suggesting that the confinement of the carbon layer on Cu could not favor C—C coupling for C₂₊ products. All the N—C/Cu catalysts showed higher selectivities to ethanol relative to the Cu and C/Cu catalysts under the same current densities (FIG. 3c). By comparing the CO₂RR performance at 300 mA cm⁻² among the catalysts, the 34% N—C/Cu catalyst displays the highest ethanol FE, higher than the Cu control by a margin of 1.7× (FIG. 3d). We further calculated the ratios of ethanol FE to ethylene FE (FEₑₜₕₐₙₒₗ/FE_{ethylene}) to evaluate the selectivity to ethanol vs. ethylene in CO₂RR (FIG. 3e). Compared with Cu, all the N—C/Cu and C/Cu catalysts exhibit higher FEₑₜₕₐₙₒₗ/FE_{ethylene}, in agreement with our calculations, indicating that the confinement of the cover on Cu is more favorable for the ethanol pathway vs. ethylene pathway.

To compare local pH at the Cu surface in N—C/Cu and Cu, we carried out the local species concentration modelling for cases with and without the N—C layer (FIG. 41). The local pH at the Cu surface is unchanged (Table 13).

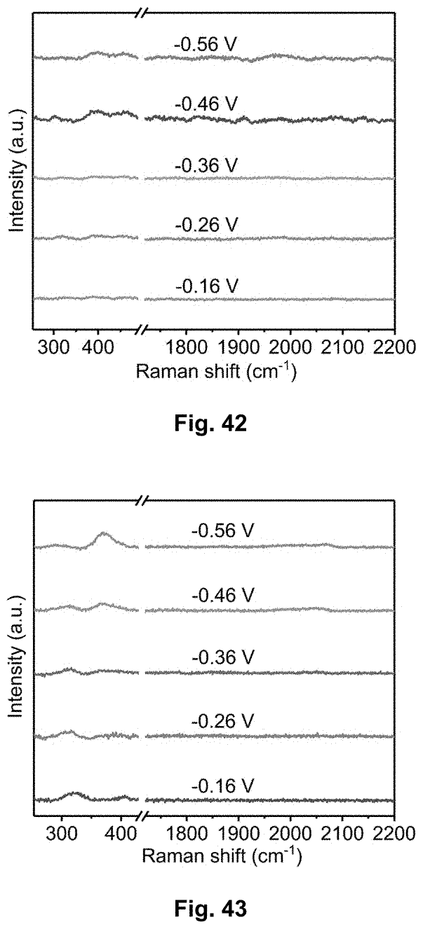

It is well known that the formation of multi-carbon products in CO₂RR goes through the formation of the carbon monoxide (CO) intermediate, and then the further reduction of CO intermediates^{11,26,27.} To gain insight into C—C coupling on 34% N—C/Cu and Cu electrodes during CO₂RR, we acquired Raman spectra in situ and investigated the interactions between the catalytic surface and the *CO intermediate (FIGS. 4a and b). Three regions in Raman spectra are associated with the surface absorbed *CO. The bands at ˜283 and ˜374 cm⁻¹ are related to the Cu—CO frustrated rotation and Cu—CO stretch, respectively^{28,29}. The band in the range of 1900-2120 cm⁻¹ can be ascribed to C≡O stretch of the surface absorbed CO, including atop-bound CO (>2000 cm⁻¹) and bridge-bound CO (1900-2000 cm⁻¹) (ref. 30,31). Raman spectra with Ar-saturated KOH were also measured as controls to reveal that it was truly CO₂-saturated conditions that gave rise to these multiple sets of peaks (FIG. 42). In situ Raman spectra shows that the peaks related to the surface absorbed *CO appear at a more positive potential on 34% N—C/Cu catalyst (−0.26 V_{RHE}) relative to the bare Cu catalyst (−0.46 V_{RHE}) (FIG. 43), indicating that the potential for CO generation on the 34% N—C/Cu is lower than that on Cu.

It was also found that, under the same potentials, the bands for the Cu—CO stretch exhibited a blueshift on the 34% N—C/Cu compared to Cu (FIG. 4b). The blueshift suggests the stronger binding of CO to N—C/Cu surface relative to Cu (ref. 32), which might promote the subsequent C—C coupling step and thus the production of C₂₊ (ref. 33). We also calculated the CO adsorption energies on the N—C/Cu and Cu models using DFT and found that the CO adsorption energy on the N—C/Cu (−0.60 eV) was also higher than that on Cu (−0.48 eV) (Table 14), consistent with our Raman results.

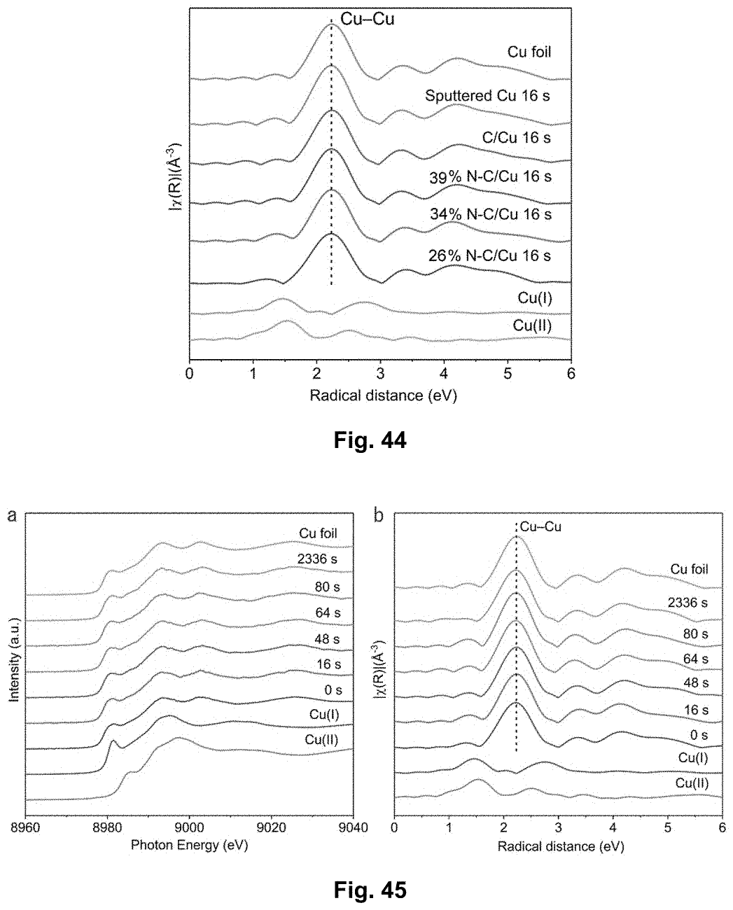

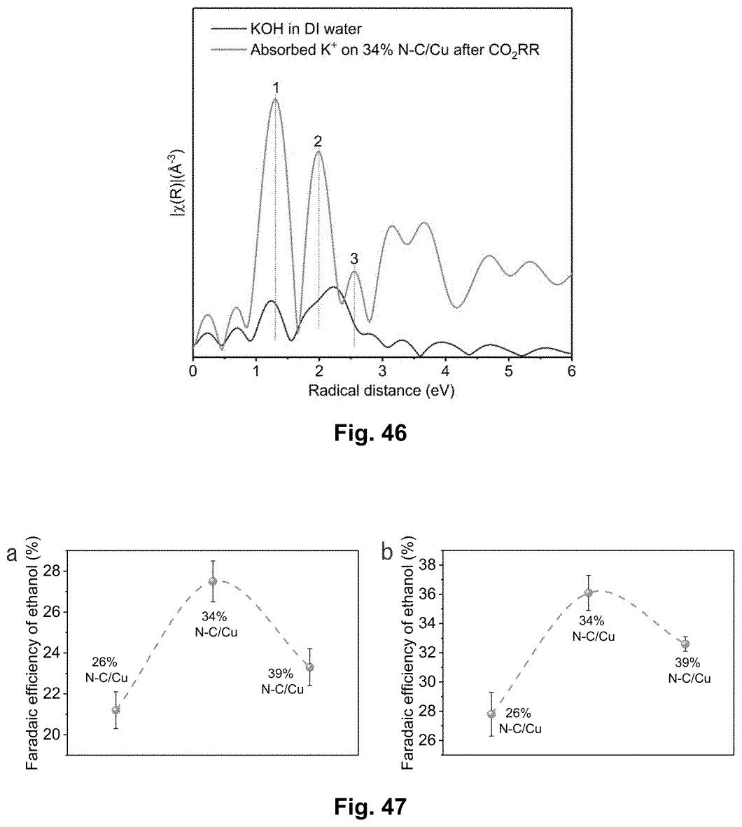

We also performed operando X-ray absorption spectroscopy (XAS) at the Cu K-edge to investigate the Cu chemical state during CO₂RR. Under the current density of 300 mA cm⁻², all copper oxides in different N—C/Cu and Cu catalysts are reduced to Cu(0) within the first 16 s, and then the valence state of Cu is maintained at zero throughout CO₂RR (FIG. 4c and FIGS. 44, 45). These operando XAS results demonstrate that the selectivity to ethanol on the N—C/Cu and Cu catalysts is associated with metallic state of Cu, rather than the existence of copper oxides^{11,34}. Additionally, there is no feature of Cu—C or Cu—N in operando XAS results³⁵, suggesting that no chemical bond is formed between Cu layer and N—C (or C) layer and thus the interaction between Cu layer and N—C(or C) layer is of the van der waals type. This is sufficient to render the N—C/Cu and C/Cu catalysts stable during the CO₂RR reaction. Ex-situ XAS at the potassium K-edge on the 34% N—C/Cu catalyst following CO₂RR shows the adsorption of K⁺ on Cu (FIG. 46), suggesting the non-continuous interface between Cu and N—C layer—supporting the results of HAADF-STEM images (FIG. 2h and FIG. 29).

It was noted that the ethanol FE shows a volcano-shape relationship with the increase of nitrogen contents under the same current densities (FIG. 3d and FIG. 47). This trend might be related to the different electron-donating abilities of N—C layers on Cu catalysts. In the N—C layer, pyridinic-N is the main factor determining the electron-donating ability as it has a lone electron pair in the plane of the carbon matrix³⁶. Among the N—C/Cu catalysts, the highest content of pyridinic-N in 34% N—C/Cu may thus lead to the highest ethanol FE (FIG. 2f and FIG. 40).

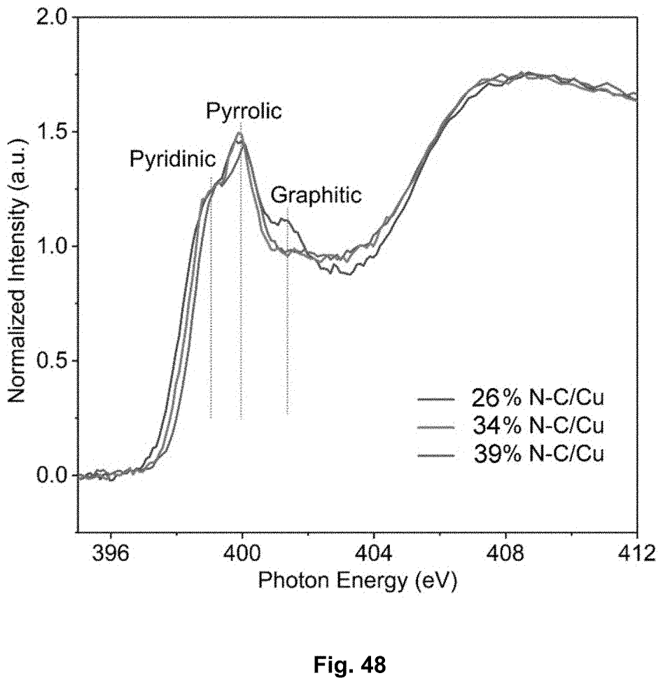

Additionally, were also acquired ex-situ X-ray absorption near edge structure (XANES) spectra at the nitrogen K-edge on different N—C/Cu catalysts in total electron yield (TEY) mode, which provided information on the near-surface chemical states³⁷ (FIG. 4d). Nitrogen K-edge XANES spectra also exhibit that there are three types of nitrogen doping (pyridinic-N, pyrrolic-N, and graphitic-N) in the N—C/Cu catalysts³⁸. As the concentration of doped nitrogen increases in the N—C layer, the main adsorption edges shift to higher energy, demonstrating that the average valence state of the nitrogen atoms (negative charge) increases in the order of 26% N—C<34% N—C/Cu<39% N—C/Cu. The nitrogen K-edge XANES spectra of different N—C/Cu catalysts recorded in a bulk-sensitive partial fluorescence yield (PFY)³⁷ also present the same trend (FIG. 48). Among these N—C/Cu catalysts, a nitrogen atom with a lower valence state represents a stronger electron-donating ability, and is thus more favorable towards the electron transfer from N—C layers to surface intermediates and ultimately promotes ethanol production during CO₂RR, as discussed in the DFT calculations. Apart from the average valence state of the nitrogen atoms, the total electron-donating ability of the N—C layer is also determined by the proportion of doped nitrogen. Therefore, the moderate valence state of the nitrogen atoms and the concentration of nitrogen in the 34% N—C/Cu catalyst might result in the strongest total electron-donating ability, thereby delivering the highest ethanol FE.

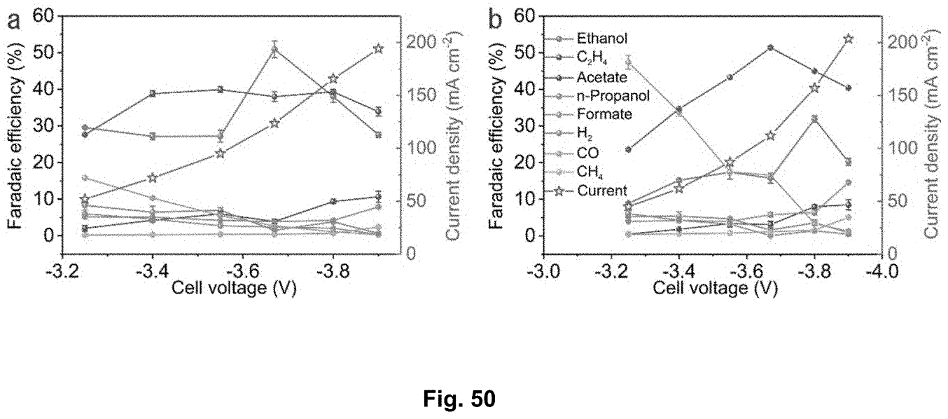

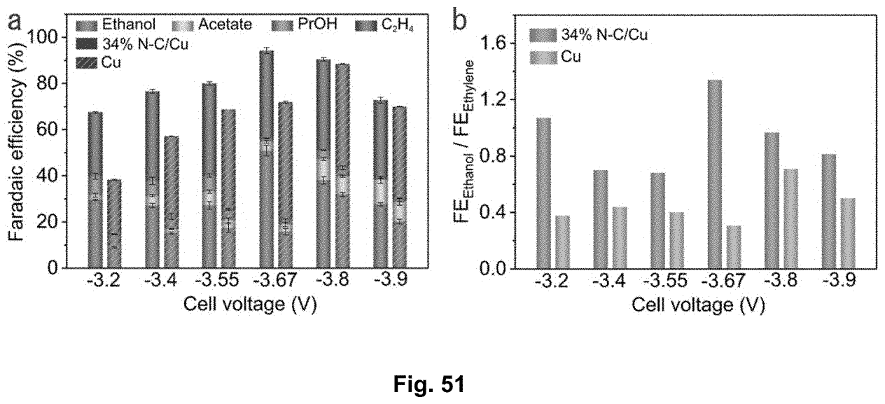

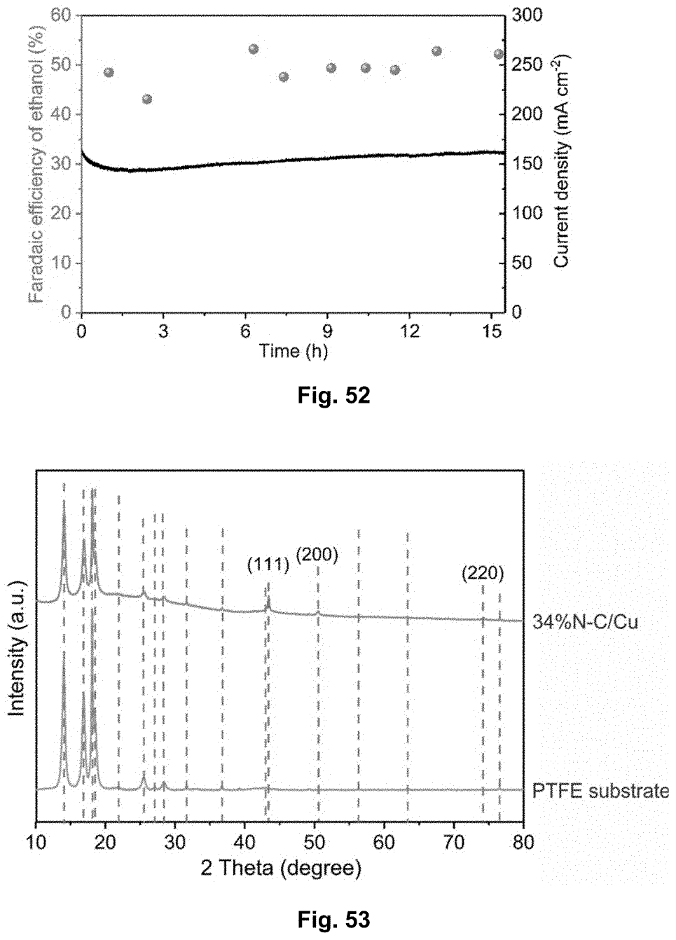

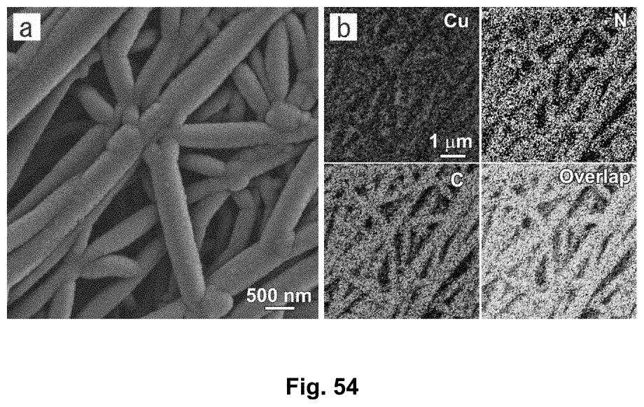

We integrated the 34% N—C/Cu catalyst into a membrane electrode assembly (MEA) system to evaluate its stability (FIG. 49). This system shows similar ethanol FE as in the alkali flow cell, and also retains the high ratio of FEₑₜₕₐₙₒₗ to FE_{ethylene} seen in the alkali system (FIGS. 50 and 51). After we operated the MEA system under the full-cell voltage of −3.67 V for 15 hours with ˜160 mA cm⁻² total current density, the system retained its ethanol FE of 52%, representing an ethanol full-cell EE of 16% (FIG. 52). XRD, SEM, and EDX elemental mapping show that N—C/Cu catalyst maintains its structure and morphology following 15 h of high-intensity electrolysis (FIGS. 43 and 54).

### 5—Supplementary Information

This section contains additional information on the experimental results reported above, including the tables mentioned in the discussion. In addition, further comments are provided with respect to FIGS. 29 and 31.

TABLE 2
Activation energies (Eₐ) and enthalpy changes (ΔH)
of CO dimerization on Cu, C/Cu, and N—C/Cu.

| | Eₐ (eV) | ΔH (eV) |
|---|---|---|
| Cu | 0.72 | 0.65 |
| C/Cu | 0.77 | 0.62 |
| N—C/Cu | 0.70 | 0.52 |

TABLE 3
Reaction energies of the intermediate state (HOCCH*)
to CCH* (ethylene pathway) and HOCHCH* (ethanol
pathway) on Cu, C/Cu, and N—C/Cu, respectively.

| | Ethylene pathway (eV) | Ethanol pathway (eV) |
|---|---|---|
| Cu | −0.09 | −0.11 |
| C/Cu | −0.09 | −0.20 |
| N—C/Cu | 0.07 | −0.03 |

The confinement effect of N—C layer on Cu(100) was considered by calculating the reaction energies of the ethylene and ethanol pathways on Cu(100) and N—C/Cu(100), as shown in Table 4. The results show that, compared to Cu(100), N—C/Cu(100) also tends to improve the ethanol selectivity vs. ethylene.

TABLE 4
Reaction energies of the ethylene and ethanol pathways and energy
differences of the ethanol and ethylene pathways on Cu(100)
and N—C/Cu(100), respectively. All the energies are in eV.

| | Ethylene | Ethanol | Ethanol pathway − |
|---|---|---|---|
| | pathway | pathway | Ethylene pathway |
| | (eV) | (eV) | (eV) |
| Cu(100) | −0.26 | −0.48 | −0.22 |
| N—C/Cu(100) | −0.47 | −0.76 | −0.29 |

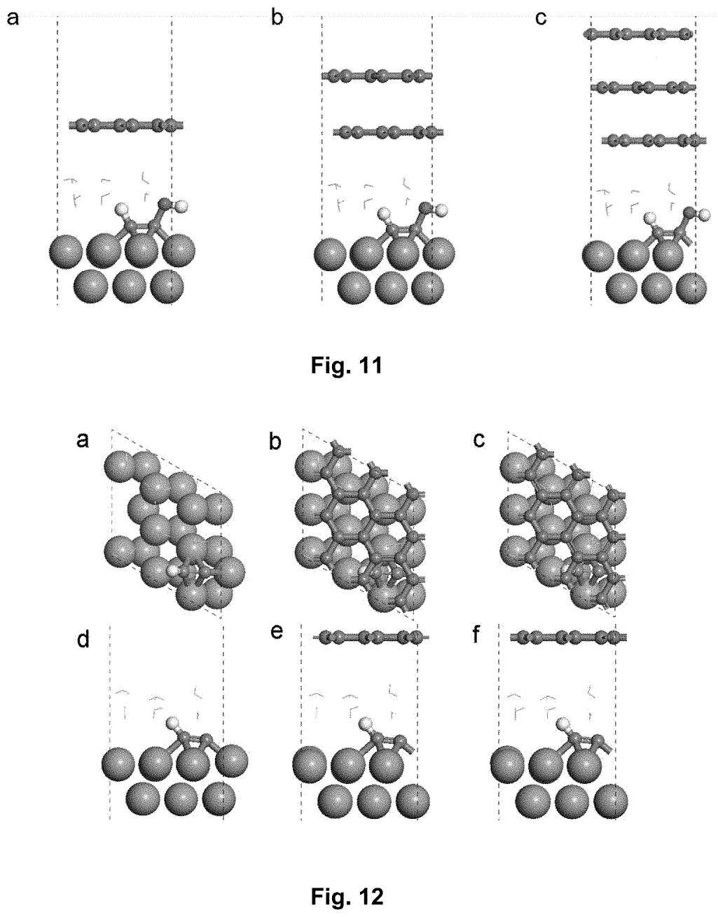

To understand the effects of different layers of graphite in CO₂RR, CO dimerization, HOCCH* to CCH* (ethylene pathway), and HOCCH* to HOCHCH* (ethanol pathway) on C/Cu was investigated with different layers of graphite carbon (Table 5 and FIG. 11). Compared to the case of graphene on Cu, the results suggest that adding multi-layer graphite on Cu almost does not change the energies of CO dimerization, nor does it change the reaction energies of the ethylene and ethanol pathways—these energies are related to the confinement effect and the electron-donating capability of the catalyst. Therefore, using a monolayer model is sufficient to describe the confinement effect, together with the electronic properties and the electron-donating capability. To simplify model, graphene and N-doped graphene were used for the calculations presented herein.

TABLE 5
Reaction energies of ethylene and ethanol pathways and activation
energies (Eₐ) and enthalpy changes (ΔH) of CO dimerization on
Cu with different layers of graphite. All the energies are in eV.

| | | |
|---|---|---|
| Ethylene | Ethanol | CO dimerization |

| Layer | pathway | pathway | Eₐ | ΔH |
|---|---|---|---|---|
| 1 | −0.09 | −0.20 | 0.77 | 0.62 |
| 2 | −0.10 | −0.21 | 0.77 | 0.63 |
| 3 | −0.10 | −0.21 | 0.77 | 0.63 |

To consider the effect of the double layer under negative potentials, we implemented the grand canonical quantum mechanics (GCQM) method (ref. 77) in JDFTX (ref. 78). The settings in the paper of Goddard and co-workers (ref. 79) were adapted. We set the ions to be 1.0 M KOH and the applied potential to be 0 V vs. standard hydrogen electrode (SHE). A comparison between the charged water model and the GCQM method is provided in Table 6. There are slight differences in absolute values, but the trends are in agreement: N—C/Cu is the best for CO dimerization, and both C/Cu and N—C/Cu favor ethanol. The high barrier of CO dimerization on C/Cu limits selectivity towards C₂ products, agreeing with the presently reported experiment results.

TABLE 6
Energy differences of the ethanol and ethylene pathways
(E_{ethanol pathway} − E_{ethylene pathway}), activation energies
(Eₐ (OC—CO)), and enthalpy changes (ΔH (OC—CO))
of CO dimerization using the charged water model and
1.0M KOH using GCQM. All the energies are in eV.

| Methods | Energy (eV) | Cu | C/Cu | N—C/Cu |
|---|---|---|---|---|
| Charged water model | E_{ethanol pathway} − | −0.02 | −0.12 | −0.11 |
| | E_{ethylene pathway} | | | |
| | Eₐ (OC—CO) | 0.72 | 0.77 | 0.70 |
| | ΔH (OC—CO) | 0.65 | 0.62 | 0.52 |
| 1.0M KOH using GCQM | E_{ethanol pathway} − | 0.09 | −0.08 | −0.01 |
| | E_{ethylene pathway} | | | |
| | Eₐ (OC—CO) | 0.82 | 0.85 | 0.77 |
| | ΔH (OC—CO) | 0.78 | 0.73 | 0.61 |

In the main calculations, the distance between N—C layer and Cu layer (d_{N—C/Cu}) in the model was 7.42 Å. This distance was obtained by relaxing the system starting from a variety of different initial structures. We set d_{N—C/Cu} to take on values ranging from 6.42 Å to 9.42 Å, fixed the graphene layer, and allowed the other atoms to be relaxed. The stabilities of these systems are shown in Table 7. The results suggest that either decreasing or increasing the d_{N—C/Cu} from 7.42 Å can lead to a decrease in stability, which suggest that 7.42 Å is the equilibrium distance between N—C layer and Cu layer due to the highest stability of the system.

We calculated the reaction energies of ethylene pathway (HOCCH* to CCH*) and ethanol pathways (HOCCH* to HOCHCH*) on N—C/Cu with the distances between N—C layer and Cu layer changing from 6.42 Å to 9.42 Å (Table 7). Similar to the results with the optimal d_{N—C/Cu} (7.42 Å) for the main calculations, N—C/Cu still tends to improve the ethanol selectivity vs. ethylene with the d_{N—C/Cu} range of 6.42 Å to 9.42 Å with respect to Cu (Table 2). Therefore, the calculation results seem to demonstrate that, ethanol selectivity can be promoted in N—C/Cu with the d_{N—C/Cu} range of 6.42 Å to 9.42 Å, compared to bare Cu.

In addition, with the change in d_{N—C/Cu}, the geometries of the key intermediate HOCCH*, the intermediate CCH*, and the intermediate HOCHCH* do not change significantly (FIGS. 14-16).

TABLE 7
Stabilities with respect to the ground state (Stability) and reaction
energies of ethylene and ethanol pathways on N—C/Cu with different
distances between N—C layer and Cu layer (d_{N—C/Cu}).

| | | Energy (eV) | | |
|---|---|---|---|---|
| d_{N—C/Cu} | | Ethylene | Ethanol | E_{ethanol pathway} − |
| (Å) | Stability | pathway | pathway | E_{ethylene pathway} |
| 6.42 | 0.45 | 0.02 | −0.24 | −0.26 |
| 7.42 | 0.00 | 0.07 | −0.03 | −0.1 |
| 8.42 | 0.19 | 0.02 | −0.01 | −0.03 |
| 9.42 | 0.37 | 0.02 | −0.11 | −0.13 |

TABLE 8
Indexes, filenames of the xyz files in paper of Deringer et al. (ref. 80), indexes
of the randomly doped nitrogen, number of carbon atoms, number of nitrogen atoms, and
formation energies per atom (E_{f}) of the top 10 most stable structures.

| | | | Number of | Number of | |
|---|---|---|---|---|---|
| | | | carbon | nitrogen | E_{f} |
| Index | Filename | Index of the randomly doped nitrogen | atoms | atoms | (eV) |
| 1 | DFT_relaxed_02_1.xyz | 28, 6, 33, 1, 0, 23, 11, 18, 33, 18 | 27 | 6 | 0.07 |
| 2 | DFT_relaxed_06_2.xyz | 25, 13, 5, 20, 42, 26, 25, 15, 17, 12, 19, 33 | 32 | 9 | 0.11 |
| 3 | DFT_relaxed_02_1.xyz | 26, 22, 12, 34, 11, 1, 24, 17, 29, 3 | 25 | 8 | 0.12 |
| 4 | DFT_relaxed_01_1.xyz | 11, 12, 4, 25, 42, 36, 30, 36, 6, 22, 6, 40 | 33 | 8 | 0.13 |
| 5 | DFT_relaxed_01_1.xyz | 35, 36, 18, 27, 17, 8, 42, 9, 11, 35, 39, 15 | 32 | 9 | 0.14 |
| 6 | DFT_relaxed_06_2.xyz | 5, 16, 24, 3, 42, 2, 28, 13, 36, 10, 12, 12 | 32 | 9 | 0.14 |
| 7 | DFT_relaxed_06_2.xyz | 24, 9, 5, 7, 22, 33, 21, 24, 8, 15, 37, 36 | 32 | 9 | 0.18 |
| 8 | DFT_relaxed_06_2.xyz | 31, 10, 15, 39, 20, 23, 10, 40, 27, 11, 7, 4 | 32 | 9 | 0.18 |
| 9 | DFT_relaxed_02_1.xyz | 14, 1, 3, 27, 26, 34, 23, 28, 7, 19 | 25 | 8 | 0.18 |
| 10 | DFT_relaxed_09_3.xyz | 8, 24, 16, 11, 3, 9, 40, 28, 12, 15, 29, 28 | 30 | 9 | 0.20 |

TABLE 9
Reaction energies of ethanol and ethylene pathways on the
top 10 most stable amorphous N-doped carbon structures. Reconstructed
structures are labeled TRUE, while unreconstructed ones are
labeled FALSE. Only the reaction energies of unreconstructed
structures are used in the calculation of average reaction
energies. All the energies are in eV.

| | Ethanol pathway | Ethylene pathway | |
|---|---|---|---|
| 1 | −0.37 | 0.22 | FALSE |
| 2 | 0.05 | 0.01 | FALSE |
| 3 | −0.35 | 0.22 | FALSE |
| 4 | 0.11 | 0.18 | FALSE |
| 5 | −0.68 | −0.15 | FALSE |
| 6 | −1.01 | −0.49 | TRUE |
| 7 | −0.09 | −0.78 | FALSE |
| 8 | 0.14 | 0.17 | FALSE |
| 9 | 0.28 | 0.18 | FALSE |
| 10 | −2.02 | 0.09 | TRUE |
| average | −0.12 | 0.01 | |

TABLE 10
Product FEs for different nanocatalysts under different applied current densities in CO₂RR.

| | Jₜₒₜₐₗ | FE_{acetate} | FEₑₜₕₐₙₒₗ | FE_{ethylene} | FEₙ₋ₚᵣₒₚₐₙₒₗ | FE_{formate} | FE_{CO} | FEₘₑₜₕₐₙₑ | FE_{hydrogen} |
|---|---|---|---|---|---|---|---|---|---|
| Catalysts | (mA cm⁻²) | (%) | (%) | (%) | (%) | (%) | (%) | (%) | (%) |
| Cu | 100 | 1.4 ± 0.4 | 17.7 ± 0.4 | 45.8 ± 2.5 | 5.6 ± 0.5 | 7.5 ± 1.1 | 6.2 ± 0.4 | 0.7 ± 0.1 | 11.9 ± 0.5 |
| | 200 | 1.8 ± 0.3 | 24.9 ± 1.3 | 51.7 ± 0.7 | 4.5 ± 0.6 | 4.5 ± 0.9 | 2.8 ± 0.3 | 1 ± 0.1 | 9.2 ± 0.5 |
| | 300 | 2.3 ± 0.3 | 31.4 ± 2.7 | 48.2 ± 1.7 | 2.6 ± 0.2 | 1.8 ± 0.5 | 1.4 ± 0.3 | 1.7 ± 0.2 | 8.9 ± 0.3 |
| 34% | 100 | 3.2 ± 0.3 | 27.5 ± 1 | 45.1 ± 3.4 | 7.7 ± 0.2 | 5.4 ± 0.8 | 2.9 ± 0.6 | 0.4 ± 0.1 | 6.6 ± 0.8 |
| N—C/Cu | 200 | 2.6 ± 0.2 | 36.1 ± 1.2 | 45.1 ± 1.7 | 3.7 ± 0.8 | 2.7 ± 0.1 | 1.2 ± 0.3 | 1.1 ± 0.1 | 5.6 ± 0.1 |
| | 300 | 2.3 ± 0.8 | 52.3 ± 0.7 | 37.5 ± 0.5 | 1.4 ± 0.1 | 1.7 ± 0.4 | 0.3 ± 0.1 | 1.2 ± 0.2 | 7.4 ± 0.9 |
| 26% | 100 | 2.7 ± 0.4 | 21.2 ± 0.9 | 46.2 ± 2 | 5.9 ± 1 | 7.5 ± 0.8 | 4.3 ± 0.4 | 0.6 ± 0.2 | 8.1 ± 0.3 |
| N—C/Cu | 200 | 2.4 ± 0.7 | 27.8 ± 1.5 | 52.2 ± 0.4 | 4.2 ± 0.8 | 2.3 ± 0.9 | 1.2 ± 0.4 | 1 ± 0.1 | 6 ± 0.2 |
| | 300 | 2 ± 0.5 | 42.6 ± 1.5 | 43.3 ± 1.5 | 0.9 ± 0.2 | 1.4 ± 0.2 | 0.6 ± 0.2 | 2.1 ± 0.8 | 7.8 ± 1.3 |
| 39% | 100 | 1.9 ± 0.4 | 23.3 ± 0.9 | 48.8 ± 0.4 | 8.6 ± 1.9 | 5.1 ± 0.4 | 3.8 ± 0.7 | 0.7 ± 0.1 | 10 ± 0.3 |
| N—C/Cu | 200 | 3.1 ± 0.3 | 32.6 ± 0.5 | 46.7 ± 1.3 | 3.7 ± 0.3 | 2.9 ± 0.2 | 1.7 ± 0.3 | 0.7 ± 0.1 | 6.4 ± 0.1 |
| | 300 | 3.6 ± 0.2 | 43.7 ± 0.8 | 44.2 ± 1.5 | 2.9 ± 0.4 | 2.4 ± 0.4 | 0.8 ± 0.1 | 2.5 ± 0.1 | 6.4 ± 0.1 |
| C/Cu | 100 | 1.8 ± 0.3 | 17.2 ± 1.1 | 41.8 ± 1.8 | 6.5 ± 1.5 | 16.3 ± 1.4 | 3.7 ± 0.6 | 0.5 | 7.4 ± 0.3 |
| | 200 | 2.7 ± 0.1 | 25 ± 1 | 49.3 ± 0.8 | 2.2 ± 1.4 | 3.5 ± 0.3 | 1.5 ± 0.4 | 2.2 ± 0.2 | 8.6 ± 0.2 |
| | 300 | 2.5 ± 0.3 | 30.5 ± 2.2 | 33.8 ± 1.6 | 1.8 ± 0.4 | 2.9 ± 0.3 | 0.6 ± 0.1 | 8.4 ± 0.3 | 20.5 ± 0.8 |

The rate-determining step of CO₂RR is widely accepted as the first a few steps of CO₂RR, including CO₂ adsorption, CO₂ activation, and *COOH hydrogenation (ref. 81). Chan, Nørskov, and co-workers (ref. 82) reported that after C—C coupling, the ensuing elementary steps are downhill. Therefore, the competing steps are HER and the first a few steps of CO₂RR. To understand the effect of confinement on HER in N—C/Cu, we investigated CO₂ adsorption, CO₂ activation, *COOH hydrogenation, and reaction energies of (H⁺+e⁻ →* H) in HER on Cu and N—C/Cu (Table 11). The results suggest that, compared to the case of Cu, CO₂ adsorption (CO₂(g)→*CO₂) is enhanced due to the confinement effect of N—C/C. In contrast, the energies of other steps (*CO₂→*COOH and *COOH→*CO) and reaction energies of (H⁺+e⁻→* H) in HER on N—C/Cu are close to these on Cu. Therefore, introducing the N—C layer does not promote HER; its impact is instead to promote CO₂RR activity. These results are consistent with the present experiment observation—H₂ FEs decrease after introducing N—C layer on Cu (Table 10).

TABLE 11
CO₂ adsorption energies (CO₂(g) → *CO₂), reaction energies of
CO₂ activation (*CO₂ → *COOH), reaction energies of
*COOH hydrogenation (*COOH → *CO), and reaction energies of
(H⁺ + e⁻ →* H) in HER on N—C/Cu and Cu. All the energies are in eV.

| | N—C/Cu | Cu |
|---|---|---|
| CO₂(g) → *CO₂ | 0.60 | 1.17 |
| *CO₂ → *COOH | 0.56 | 0.44 |
| *COOH → *CO | −0.50 | −0.54 |
| H⁺ + e⁻ →* H | −0.05 | −0.06 |

TABLE 12
Cu_{ECSA} determined by Pd_{UPD} method for different samples.

| | Cu_{ECSA} (cm²) |
|---|---|
| Cu | 6.42 |
| 26% N—C/Cu | 4.41 |
| 34% N—C/Cu | 5.91 |
| 39% N—C/Cu | 5.65 |

TABLE 13
Local pH at Cu surfaces for cases
with and without the N—C layer.

| | With N—C on Cu | Only Cu |
|---|---|---|
| Local pH | 13.9 | 13.9 |

TABLE 14
Adsorption energies of CO (E_{CO}) on pure Cu, C/Cu, and
N—C/Cu. The adsorption energies are calculated with
structures in FIG. 6 with two CO molecules, and the energies
listed below are the average adsorption energies.

| | E_{CO} (eV) |
|---|---|
| Cu | −0.48 |
| C/Cu | 0.10 |
| N—C/Cu | −0.60 |

Supplementary Information about FIG. 29

The images used for the analysis of the gap are obtained with the camera not saturated in any regions of the field surveyed in these images (FIG. 2h,i and FIG. 29). The intensity profile of the reduced region thus is used for determining the gap width, by taking the width of the half minimum value. The measurement shows that the gap between Cu and N—C layers are generally below 1 nm (FIG. 2h,i and FIG. 29). If the N—C layer is closely attached to the Cu layer, one should expect the intensity profile shows a steady increase till the contrast from the Cu layer contribution. The dips in the intensity profiles (FIG. 2i and FIG. 29b) on the other hand demonstrate the presence of a small gap between N—C layer and Cu layer.

Supplementary Information about FIG. 31

The resistance (R) between the working and reference electrodes with 34% N—C/Cu catalyst was measured in the course of constant-current (300 mA cm⁻²) electrolysis through electrochemical impedance spectroscopy (EIS) technique, and the corresponding iR drop was calculated (FIG. 31). The results show that both the R and iR drop gradually increase during electrolysis, and the resistance increases from 5.5 n at the beginning of the electrolysis to 6.5Ω after 20 min electrolysis. Considering that R increases during the electrolysis, the potential is corrected based on the lowest R—the R at the beginning of the electrolysis.

### 6—Conclusions and Outlook

Confinement by covering an active copper-based electrocatalyst to enable molecules and solutions to intercalate was exploited to increase selectivity for ethanol. Density functional theory (DFT) calculations suggested that coating a nitrogen-doped carbon (N—C) layer on a Cu surface promotes C—C coupling and suppresses the breaking of the C—O bond in HOCCH*, thereby promoting ethanol selectivity in CO₂RR. This was made possible by the strong electron-donating ability of the confining N—C layer. The catalyst delivered an ethanol FE of (52±1) % and an ethanol cathodic energy efficiency (EE) of 31%.

More particularly, this work thus showed how confinement effect arising due to an N—C layer on Cu catalysts, taken together with the strong electron-donating ability of the N—C layer, can enable advances in selectivity towards ethanol in CO₂RR. An ethanol FE of (52±1) % with a partial ethanol current density (156±3) mA cm⁻² on 34% N—C/Cu catalyst in CO₂RR was observed. The cathodic EE and full-cell EE for ethanol also achieved a high value of 31% and 16%, respectively. These findings provide a route to improve the selectivity toward high-energy-density ethanol in CO₂RR through catalyst design.

### REFERENCES

The following references are hereby incorporated herein by reference in their entirety:
1. Jhong, H.-R., Ma, S. & Kenis, P. J. A. Electrochemical conversion of CO₂ to useful chemicals: current status, remaining challenges, and future opportunities. Curr. Opin. Chem. Eng. 2, 191-199 (2013).
2. Hori, Y. “Electrochemical CO₂ Reduction on Metal Electrodes” in Modern Aspects of Electrochemistry no. 42, Vayenas, C. G., White, R. E. & Gamboa-Aldeco, M. E. Eds. (Springer, 2008), chap. 3.
3. Qiao, J., Liu, Y., Hong, F. & Zhang, J. A review of catalysts for the electroreduction of carbon dioxide to produce low-carbon fuels. Chem. Soc. Rev. 43, 631-675 (2014).
4. Zhou, Y. et al. Dopant-induced electron localization drives CO₂ reduction to C₂ hydrocarbons. Nat. Chem. 19, 974-980 (2018).
5. Ren, R. et al. Molecular electrocatalysts can mediate fast, selective CO₂ reduction in a flow cell. Science 365, 367-369 (2019).
6. Dinh, C.-T. et al. CO₂ electroreduction to ethylene via hydroxide-mediated copper catalysis at an abrupt interface. Science 360, 783-787 (2018).
7. Xia, C. et al. Continuous production of pure liquid fuel solutions via electrocatalytic CO₂ reduction using solid-electrolyte devices. Nat. Energy 4, 776-785 (2019).
8. Jouny, M., Luc, W. & Jiao, F. General techno-economic analysis of CO₂ electrolysis systems. Ind. Eng. Chem. Res. 57, 2165-2177 (2018).
9. Global Ethanol Market: Advancement in Production Technologies to boost Market, notes TMR, Transparency Market Research. www.transparencymarket-research.com/pressrelease/ethanol-market.htm (2018).
10. Lum, Y., Cheng, T., Goddard, W. A. & Ager, J. W. Electrochemical CO reduction builds solvent water into oxygenate products. J. Am. Chem. Soc. 140, 9337-9340 (2018).
11. Cheng, T., Xiao, H. & Goddard, W. A. Full atomistic reaction mechanism with kinetics for CO reduction on Cu(100) from ab initio molecular dynamics free-energy calculations at 298 K. Proc. Natl. Acad. Sci. U.S.A. 114, 1795-1800 (2017).
12. Hoang, T. T. H. et al. Nanoporous copper-silver alloys by additive-controlled electrodeposition for the selective electroreduction of CO₂ to ethylene and ethanol. J. Am. Chem. Soc. 140, 5791-5797 (2018).
13. Zhuang, T.-T. et al. Steering post-C—C coupling selectivity enables high efficiency electroreduction of carbon dioxide to multi-carbon alcohols. Nat. Catal. 1, 421-428 (2018).
14. Wu, J. et al. A metal-free electrocatalyst for carbon dioxide reduction to multi-carbon hydrocarbons and oxygenates. Nat. Commun. 7, 13869 (2016).
15. Hoang, T. T. H., Ma, S., Gold, J. I., Kenis, P. J. A. & Gewirth, A. A. Nanoporous copper films by additive-controlled electrodeposition: CO₂ reduction catalysis. ACS Catal. 7, 3313-3321 (2017).
16. Li, F. et al. Cooperative CO₂-to-ethanol conversion via enriched intermediates at molecule-metal catalyst interfaces. Nat. Catal. 3, 75-82 (2020).
17. Li, H., Xiao, J., Fu, Q. & Bao, X. Confined catalysis under two-dimensional materials. Proc. Natl. Acad. Sci. U.S.A 114, 5930-5934 (2017).
18. Qiang, F. & Bao, X. Surface chemistry and catalysis confined under two-dimensional materials. Chem. Soc. Rev. 46, 1842-1874 (2017).
19. Zicovich-Wilson, C., Corma, A. & Viruela, P. Electronic confinement of molecules in microscopic pores. A new concept which contributes to the explanation of the catalytic activity of zeolites. J. Phys. Chem. 98, 10863-10870 (1994).
20. Yang, F., Deng, D., Pan, X., Fu, Q. & Bao, X. Understanding nano effects in catalysis. Natl. Sci. Rev. 2, 183-201 (2015).
21. Calle-Vallejo, F. & Koper, M. T. M. Theoretical considerations on the electroreduction of CO to C₂ species on Cu(100) electrodes. Angew. Chem. Int. Ed. 52, 7282-7285 (2013).
22. Kumar, B. et al. Renewable and metal-free carbon nanofiber catalysts for carbon dioxide reduction. Nat. Commun. 4, 2918 (2013).
23. Wu, J. et al. A metal-free electrocatalyst for carbon dioxide reduction to multi-carbon hydrocarbons and oxygenates. Nat. Commun. 7, 13869 (2016).
24. Krivanek, O. L. et al. Atom-by-atom structural and chemical analysis by annular dark-field electron microscopy. Nature 464, 571-574 (2010).
25. Zhuang, T.-T. et al. Copper nanocavities confine intermediates for efficient electrosynthesis of C₃ alcohol fuels from carbon monoxide. Nat. Catal. 1, 946-951 (2018).
26. Kortlever, R., Shen, J., Schouten, K. J. P., Calle-Vallejo, F. & Koper, M. T. M. Catalysts and reaction pathways for the electrochemical reduction of carbon dioxide. J. Phys. Chem. Lett. 6, 4073-4082 (2015).
27. Montoya, J. H., Shi, C., Chan, K. & Norskov, J. K. Theoretical insights into a CO dimerization mechanism in CO₂. J. Phys. Chem. Lett. 6, 2032-2037 (2015).
28. Chernyshova, I., Somasundaran, P. & Ponnurangam, S. On the origin of the elusive first intermediate of CO₂ electroreduction. Proc. Natl. Acad. Sci. U.S.A. 115, E9261-E9270 (2018).
29. Akemann, W. & Otto, A. Vibrational modes of CO adsorbed on disordered copper films. J. Raman Spectrosc. 22, 797-803 (1991).
30. Gunathunge, C. M. et al. Spectroscopic observation of reversible surface re-construction of copper electrodes under CO₂ reduction. J. Phys. Chem. C 121, 12337-12344 (2017).
31. Sheppard, N. & Nguyen, T. T. in Advances in Infrared and Raman Spectroscopy, Clark, R. J. H. & Hester, R. E. Eds (Heyden, London, 1978), vol. 5.
32. Fielicke, A., Gruene, P., Meijer, G. & Rayner, D. M. The adsorption of CO on transition metal clusters: A case study of cluster surface chemistry. Sur. Sci. 603, 1427-1433 (2009).
33. Sandberg, R. B., Montoya, J. H., Chan, K. & Norskov, J. K. CO—CO coupling on Cu facets: Coverage, strain and field effects. Sur. Sci. 654, 56-62 (2016).
34. Li, J. et al. Copper adparticle enabled selective electrosynthesis of n-propanol. Nat. Commun. 9, 4614 (2018).
35. Huan, T. N. et al. From molecular copper complexes to composite electrocatalytic materials for selective reduction of CO₂ to formic acid. J. Mater. Chem. A 3, 3901-3907 (2015).
36. Liu, G., Li, X., Ganesan, P. & Popov, B. N. Development of non-precious metal oxygen-reduction catalysts for PEM fuel cells based on N-doped ordered porous carbon. Appl. Catal. B. 93, 156-165 (2009).
37. Li, J. et al. Unraveling the origin of visible light capture by core-shell TiO₂ nano-tubes. Chem. Mater. 28, 4467-4475 (2016).
38. Niwa, H. et al. X-ray absorption analysis of nitrogen contribution to oxygen reduction reaction in carbon alloy cathode catalysts for polymer electrolyte fuel cells. J. Power Sources 187, 93-97 (2009).
39. Luc, W., Rosen, J. & Jiao, F. An Ir-based anode for a practical CO₂ electrolyzer. Catal. Today 288, 79-84 (2017).
40. Ravel, B. & Newville, M. ATHENA, ARTEMIS, HEPHAESTUS: data analysis for X-ray absorption spectroscopy using IFEFFIT. J. Synchrotron Radiat. 12, 537-541 (2005).
41. Jan, I. Nika: software for two-dimensional data reduction. J. Appl. Crystallogr. 45, 324-328 (2012).
42. Urbain, F. et al. A prototype reactor for highly selective solar-driven CO₂ reduction to synthesis gas using nanosized earth-abundant catalysts and silicon photovoltaics. Energy Environ. Sci., 10, 2256-2266 (2017).
43. Baturina, O. A. et al. CO₂ electroreduction to hydrocarbons on carbon-supported Cu nanoparticles. ACS Catal. 4, 3682-3695 (2014).
44. Kuhl, K. P., Cave, E. R., Abram, D. N. & Jaramillo, T. F. New insights into the electrochemical reduction of carbon dioxide on metallic copper surfaces. Energy Environ. Sci. 5, 7050-7059 (2012).
45. Kresse, G. & Furthmüller, J. Efficient iterative schemes for ab initio total-energy calculations using a plane-wave basis set. Phys. Rev. B 54, 11169-11186 (1996).
46. Kresse, G. & Furthmuller, J. Efficiency of ab-initio total energy calculations for metals and semiconductors using a plane-wave basis set. Comp. Mater. Sci. 6, 15-50 (1996).
47. Kresse, G. & Hafner, J. Ab initio molecular-dynamics simulation of the liquid-metal amorphous-semiconductor transition in germanium. Phys. Rev. B 49, 14251-14269 (1994).
48. Kresse, G. & Hafner, J. Ab initio molecular dynamics for liquid metals. Phys. Rev. B 47, 558-561 (1993).
49. Perdew, J. P., Burke, K. & Ernzerhof, M. Generalized gradient approximation made simple. Phys. Rev. Lett. 77, 3865-3868 (1996).
50. Kresse, G. & Joubert, D. From ultrasoft pseudopotentials to the projector augmented-wave method. Phys. Rev. B 59, 1758-1775 (1999).
51. Blöchl, P. E. Projector augmented-wave method. Phys. Rev. B 50, 17953-17979 (1994).
52. Grimme, S., Antony, J., Ehrlich, S. & Krieg, H. A consistent and accurate ab initio parametrization of density functional dispersion correction (DFT-D) for the 94 elements H-Pu. J. Chem. Phys. 132, 154104 (2010).
53. Michaelides, A. et al. Identification of general linear relationships between activation energies and enthalpy changes for dissociation reactions at surfaces. J. Am. Chem. Soc. 125, 3704-3705 (2003).
54. Liu, Z. P. & Hu, P. General rules for predicting where a catalytic reaction should occur on metal surfaces: A density functional theory study of C—H and C—O bond breaking/making on flat, stepped, and kinked metal surfaces. J. Am. Chem. Soc. 125, 1958-1967 (2003).
55. Alavi, A., Hu, P. J., Deutsch, T., Silvestrelli, P. L. & Hutter, J. CO oxidation on Pt(111): An ab initio density functional theory study. Phys. Rev. Lett. 80, 3650-3653 (1998).
56. Montoya, J. H., Shi, C., Chan, K. & Nørskov, J. K. Theoretical insights into a CO dimerization mechanism in CO₂ electroreduction. J. Phys. Chem. Lett. 6, 2032-2037 (2015).
57. Deringer, V. L. et al. Computational surface chemistry of tetrahedral amorphous carbon by combining machine learning and density functional theory. Chem. Mater. 30, 7438-7445 (2018).
58. Gupta, N., Gattrell, M. & MacDougall, B. Calculation for the cathode surface concentrations in the electrochemical reduction of CO₂ in KHCO₃ solutions. J. Appl. Electrochem. 36, 161-172 (2006).
59. Burdyny, T. et al. Nanomorphology-enhanced gas-evolution intensifies CO₂ reduction electrochemistry. ACS Sustain. Chem. Eng. 5, 4031-4040 (2017).
60. Wiesenburg, D. A. & Guinasso, N. L. J. Equilibrium solubilities of methane, carbon monoxide, and hydrogen in water and sea water. Chem. Eng. Data 24, 356-360 (1979).
61. Linstrom, P. J. & Mallard, W. G. NIST Chemistry WebBook, NIST Standard Reference Database Number 69. https://doi.org/10.18434/T4D303 (2018).
62. Schumpe, A. & Weisenberger, S. Estimation of gas solubilities in salt solutions at temperatures from 273 K to 363 K. AlChE J. 42, 298-300 (1996).
63. Millero, F. J., Graham, T. B., Huang, F., Bustos-Serrano, H. & Pierrot, D. Dissociation constants of carbonic acid in seawater as a function of salinity and temperature. Mar. Chem. 100, 80-94 (2006).
64. Schulz, K. G., Riebesell, U., Rost, B., Thoms, S. & Zeebe, R. E. Determination of the rate constants for the carbon dioxide to bicarbonate inter-conversion in pH-buffered seawater systems. Mar. Chem. 100, 53-65 (2006).
65. Millero, F. J. & Rabindra, N. R. A chemical equilibrium model for the carbonate system in natural waters. Croat. Chem. Acta 70, 1-38 (1997).
66. Mehrbach, C., Culberson, C. H., Hawley, J. E. & Pytkowicx, R. M. Measurement of the apparent dissociation constants of carbonic acid in seawater at atmospheric pressure. Limnol Oceanogr. 18, 897-907 (1973).
67. Vanysek, P. CRC Handbook of Chemistry and Physics (CRC Press, 1993).
68. Raciti, D., Mao, M. & Wang, C. Mass transport modelling for the electroreduction of CO₂ on Cu nanowires. Nanotechnology 29, 044001 (2017).
69. Sacco, A., Zeng, J., Bejtka, K. & Chiodoni, A. Modeling of gas bubble-induced mass transport in the electrochemical reduction of carbon dioxide on nanostructured electrodes. J. Catal. 372, 39-48 (2019).
70. Newman, J. & Thomas-Alyea, K. E. Electrochemical Systems (John Wiley & Sons, Inc, 2004).
71. Bernardi, D. M. & Verbrugge, M. W. Mathematical model of a gas diffusion electrode bonded to a polymer electrolyte. AlChE J. 37, 1151-1163 (1991).
72. Das, P. K., Li, X. & Liu, Z.-S. Effective transport coefficients in PEM fuel cell catalyst and gas diffusion layers: beyond Bruggeman approximation. Appl. Energy 87, 2785-2796 (2010).
73. Van Oversteeg, C. H. M., Doan, H. Q., de Groot, F. M. F. & Cuk, T. In situ x-ray absorption spectroscopy of transition metal based water oxidation catalysts. Chem. Soc. Rev. 46, 102-125 (2017).
74. Li, Q et al. A unified intermediate and mechanism for soot combustion on potassium-supported oxides. Sci. Rep. 4, 4725 (2014).
75. Kiguchi, M., Entani, S., Saiki, K., Inoue, H. & Koma, A. Two types of epitaxial orientations for the growth of alkali halide on fcc metal substrates. Phys. Rev. B 66, 155424 (2002).
76. Kiguchi, M., Yoshikawa, G., Ikeda, S. & Saiki, K. Electronic properties of metal-induced gap states formed at alkali-halide/metal interfaces. Phys. Rev. B 71, 153401 (2005).
77. Sundararaman, R., Goddard III, W. A. & Arias, T. A. Grand canonical electronic density-functional theory: Algorithms and applications to electrochemistry. J. Chem. Phys. 146, 114104 (2017).
78. Sundararaman, R. et al. JDFTx: Software for joint density-functional theory. SoftwareX 6, 278-284 (2017).
79. Xiao, H., Cheng, T. & Goddard III, W. A. Atomistic mechanisms underlying selectivities in C₁ and C₂ products from electrochemical reduction of CO on Cu(111). J. Am. Chem. Soc. 139, 130-136 (2017).
80. Deringer, V. L. et al. Computational surface chemistry of tetrahedral amorphous carbon by combining machine learning and density functional theory. Chem. Mater. 30, 7438-7445 (2018).
81. Chernyshova, I. V., Somasundaran, P. & Ponnurangam, S. On the origin of the elusive first intermediate of CO₂ electroreduction. Proc. Natl. Acad. Sci. 115, E9261-E9270 (2018).
82. Liu, X. et al. pH effects on the electrochemical reduction of CO₍₂₎ towards C₂ products on stepped copper. Nat. Commun. 10, 32 (2019).

1. A catalytic system comprising a fibrous hydrophobic substrate, a first layer having a first layer thickness comprising copper or copper alloy nanoparticles covering the polymeric substrate, and a second layer having a second layer thickness over the first layer and comprising amorphous nitrogen-doped carbon, wherein the catalytic system comprises confined interlayer spaces defined by regions where the first layer and the second layer are spaced apart from each other.

2. The catalytic system of claim 1, wherein the fibrous hydrophobic substrate comprises polymeric nanofibers, carbon nanofibers, or a combination thereof.

3. The catalytic system of claim 1, wherein the fibrous hydrophobic substrate comprises at least one fluoropolymer.

4. The catalytic system of claim 1, wherein the fibrous hydrophobic substrate comprises polytetrafluoroethylene (PTFE).

5. The catalytic system of claim 1, wherein the fibrous hydrophobic substrate comprises a nanofibers membrane.

6. The catalytic system of claim 1, wherein the fibrous hydrophobic substrate comprises a nanofibers membrane having a pore size ranging from about 200 nm to about 700 nm.

7. The catalytic system of claim 1, wherein the fibrous hydrophobic substrate comprises nanofibers having a diameter ranging from about 50 nm to about 200 nm.

8. The catalytic system of claim 1, wherein the first layer thickness is from about 100 nm to about 500 nm and the second layer thickness is from about 20 nm to about 100 nm.

9. The catalytic system of claim 1, wherein the copper or copper alloy nanoparticles have a diameter ranging from about 20 nm to about 100 nm.

10. The catalytic system of claim 1, wherein in the second layer, the amorphous nitrogen-doped carbon comprises electron-donating nitrogen atoms.

11. The catalytic system of claim 1, wherein an atomic percentage of nitrogen in the second layer is from about 3% to about 50%.

12. The catalytic system of claim 1, wherein the second layer comprises pyridinic-N, pyrrolic-N and graphitic-N.

13. The catalytic system of claim 11, wherein a content of pyridinic-N is higher than a content of pyrrolic-N or graphitic-N.

14. The catalytic system of claim 1, wherein the second layer comprises pyridinic-N in an atomic percentage from about 10% to about 21%.

15. The catalytic system of claim 1, wherein the second layer comprises a plurality of pores extending through the second layer thickness.

16. The catalytic system of claim 15, wherein the pores in the second layer have an average diameter from about 5 nm to about 20 nm.

17. The catalytic system of claim 1, wherein the first layer and the second layer are spaced apart from each other in the confined interlayer spaces by a distance that is about 1 nm or below.

18. A membrane electrode assembly system comprising a cathode side and an anode side, wherein the cathode side comprises the catalytic system as defined in claim 1.

19. A method for electrochemical reduction of carbon dioxide, carbon monoxide, or a combination thereof, comprising:
contacting a reactant gas comprising carbon dioxide, carbon monoxide, or a combination thereof, in the presence of an electrolyte, with a cathode comprising the catalytic system as defined in claim 1;
applying a voltage to provide a current density to cause the carbon dioxide, carbon monoxide, or the combination thereof, in the reactant gas contacting the cathode, to be electrochemically reduced.

20. A method for electrochemical production of ethanol from carbon dioxide, carbon monoxide, or a combination thereof, comprising:
contacting a reactant gas comprising carbon dioxide, carbon monoxide, or a combination thereof, in the presence of an electrolyte, with a cathode comprising the catalytic system as defined in claim 1;
applying a voltage to provide a current density to cause the carbon dioxide, carbon monoxide, or the combination thereof in the reactant gas contacting the cathode, to be electrochemically converted into ethanol.

21. A process for producing a catalytic system as defined in claim 1, comprising:
sputtering copper or the copper alloy onto the fibrous hydrophobic substrate to form the first layer; and
sputtering the nitrogen-doped carbon onto the first layer to form the second layer.
